(19) United States
(12) Patent Application Publication
(10) Pub. No.: US 2012/0138342 A1
(43) Pub. Date: Jun. 7, 2012

(54) CONDUCTIVE OPTICAL DEVICE, INFORMATION INPUT APPARATUS, AND DISPLAY APPARATUS

(75) Inventors: Yutaka Muramoto, Miyagi (JP); Shunichi Kajiya, Miyagi (JP); Kazuya Hayashibe, Miyagi (JP)

(73) Assignee: SONY CORPORATION, Tokyo (JP)

(21) Appl. No.: 13/278,652

(22) Filed: Oct. 21, 2011

(30) Foreign Application Priority Data
Dec. 7, 2010 (JP) 2010-272340

(51) Int. Cl. H05K 1/02; B32B 3/00

(52) U.S. Cl. 174/254; 428/156

(57) ABSTRACT

Provided is a conductive optical device including a substrate having flexibility; structural elements which are constructed with a plurality of convex portions or concave portions with a fine pitch which is equal to or less than the wavelength of visible light arranged on a surface of the substrate; and a transparent conductive layer which is formed on the structural elements, wherein the aspect ratio of the structural elements is equal to or more than 0.1 and equal to or less than 1.8, wherein the transparent conductive layer has a surface emulating the structural elements, and wherein a conductivity with respect to the bending test is maintained.

### CROSS REFERENCES TO RELATED APPLICATIONS

The present application claims priority to Japanese Patent Application No. 2010-272340 filed on Dec. 7, 2010, the disclosure of which is incorporated herein by reference.

### BACKGROUND

The present disclosure relates to a conductive optical device, an information input apparatus, and a display apparatus, and more particularly, to a conductive optical device where a transparent conductive layer is formed on one main surface.

Recently, a touch panel for inputting information has been disposed on a display apparatus included in a mobile apparatus, mobile phone, or the like.

For example, a resistive film type touch panel has a structure where two transparent conductive films are disposed to face each other through spacers constructed with an insulating material such as an acryl resin, and the transparent conductive films function as electrodes of the touch panel. The transparent conductive film includes a substrate having transparency such as a polymer film and a transparent conductive layer formed on the substrate.

As a transparent conductive layer constituting the transparent conductive film, a thin film of an inorganic conductive compound formed by using a material having a high refractive index (for example, about 1.9 to about 2.1) such as an ITO (Indium Tin Oxide) has been widely used. However, the thin film of the inorganic conductive compound has an insufficient flexibility, and thus, the transparent conductive film has poor bendability.

If the transparent conductive layer is formed to be thin so as to improve the bendability of the transparent conductive film, it is difficult to obtain a surface resistance value of, for example, about 50Ω/to about 500Ω/, which is necessary for the transparent conductive film. On the other hand, in order to implement a desired surface resistance value, if the transparent conductive layer is formed to be thick, the bendability and the transmittance of the transparent conductive film deteriorate. In such a manner, it is difficult to simultaneously implement the bendability, the low resistance, and the high transmittance of the transparent conductive film.

In order to solve this problem, for example, Japanese Unexamined Patent Application Publication No. 2009-302029 discloses a flexible transparent conductive film where a transparent conductive layer is formed by applying an application liquid containing conductive oxide particles and a binder matrix on a plastic film having a gas barrier function. In addition, for example, Japanese Unexamined Patent Application Publication No. 2010-225375 discloses a transparent conductive film obtained by first forming a layer of an organic polymer conductive compound on a transparent organic polymer film and forming a layer of an inorganic conductive compound thereon.

### SUMMARY

However, in the transparent conductive film disclosed in Japanese Unexamined Patent Application Publication No. 2009-302029 or 2010-225375, if the low resistance is to be realized, the thickness of the transparent conductive layer increases, such that sufficient bendability may not be obtained.

Therefore, it is desirable to provide a conductive optical device, an information input apparatus, and display apparatus capable of securing low resistance and high transmittance while maintaining conductivity with respect to bending.

According to an embodiment of the present disclosure, there is provided a conductive optical device including: a substrate having flexibility; structural elements which are constructed with a plurality of convex portions or concave portions with a fine pitch which is equal to or less than the wavelength of visible light arranged on a surface of the substrate; and a transparent conductive layer which is formed on the structural elements, wherein the aspect ratio of the structural elements is equal to or more than 0.1 and equal to or less than 1.8, wherein the transparent conductive layer has a surface emulating the structural elements, and wherein a conductivity with respect to the bending test is maintained.

In the present disclosure, it is preferable that the substrate including the structural elements and the transparent conductive layer have flexibility. In the case where the configuration is employed, it is preferable that the aspect ratio of the structural elements be set to be equal to or more than 0.1 and equal to or less than 1.8, and the transparent conductive layer has a surface emulating the structural elements. This is because it is possible to maintain the conductivity with respect to the bending test. The phrase “to maintain the conductivity with respect to the bending test” is defined specifically by the state in which the change between the measured value of the interterminal resistance after the winding around of a 44 metal bar and the resistance value of the interterminal resistance before the winding (no bending) is in a range of equal to or less than 50%. In the case where the conductive optical device is used as a transparent conductive film, in terms of simultaneous implementation of the bendability, the low resistance, and the high transmittance, it is preferable that the surface resistance of the transparent conductive layer be set to be in a range of equal to or more than 50Ω/and less than 500Ω/.

It is preferable that the thickness of the transparent conductive layer in a top portion of the structural element be in a range of equal to or more than 5 nm and equal to or less than 150 nm.

In the present disclosure, it is preferable that the structural elements be arranged so as to constitute a plurality of columns of tracks on the surface of the substrate. It is preferable that a plurality of columns of the tracks have, for example, a straight line shape or an arc shape, or it is preferable that a plurality of columns of the tracks be formed to meander.

In the present disclosure, it is preferable that the structural elements be arranged periodically in a hexagonal lattice shape or a quasi-hexagonal lattice shape. Herein, the hexagonal lattice denotes a regular hexagonal shaped lattice. Unlike a regular hexagonal shaped lattice, the quasi-hexagonal lattice denotes a deformed regular hexagonal shaped lattice.

For example, in the case where the structural elements are arranged in a straight line, the quasi-hexagonal lattice denotes a hexagonal lattice formed by extending the regular hexagonal shaped lattice in a straight line shape arrangement direction (track direction) to be deformed. In the case where the structural elements are arranged to meander, the quasi-hexagonal lattice denotes a hexagonal lattice formed by deforming the regular hexagonal shaped lattice by the meandering arrangement of the structural elements. In addition, the quasi-hexagonal lattice denotes a hexagonal lattice deformed by extending the regular hexagonal shaped lattice in a straight line shape arrangement direction (track direction) to be deformed and by deforming the regular hexagonal shaped lattice by the meandering arrangement of the structural elements.

In addition, it is preferable that the structural elements be arranged periodically in a square lattice shape or a quasi-square lattice shape. Herein, the square lattice denotes a regular square shaped lattice. Unlike the regular square shaped lattice, the quasi-square lattice denotes a deformed regular square shaped lattice.

For example, in the case where the structural elements are arranged in a straight line, the quasi-square lattice denotes a square lattice formed by extending the regular square shaped lattice in a straight line shape arrangement direction (track direction) to be deformed. In the case where the structural elements are arranged to meander, the quasi-square lattice denotes a square lattice formed by deforming the regular square shaped lattice by the meandering arrangement of the structural elements. In addition, the quasi-square lattice denotes a square lattice formed by extending the regular square shaped lattice in a straight line shape arrangement direction (track direction) to be deformed and by deforming the regular square shaped lattice by the meandering arrangement of the structural elements.

In the present disclosure, it is preferable that the structural elements have an elliptical cone shape or a truncated elliptical cone shape having the direction of the longest axis in the track extension direction. In the present disclosure, the ellipse includes an ellipse which is somewhat deformed as well as an ideal ellipse which is mathematically defined. The circular shape includes a circular shape which is somewhat deformed as well as an ideal circle which is mathematically defined.

In the present disclosure, a plurality of the structural elements arranged on the surface of the substrate with the fine pitch constitute a plurality of columns of the tracks, and form a hexagonal lattice pattern, a quasi-hexagonal lattice pattern, a square lattice pattern, or a quasi-square lattice pattern among the three adjacent columns of the tracks. Therefore, it is possible to increase a packing density of the structural elements on the surface, so that it is possible to improve a reflection preventing efficiency of visible light or the like. Therefore, it is possible to obtain a conductive optical device having an excellent reflection preventing characteristic and a high transmittance.

In addition, it is preferable that, in the case where fine arrangement of the structural elements is formed on the main surface of the side opposite to the one main surface as well as the one main surface, for example, in the case where the light incidence surface and the light emitting surface are provided to both of the two sides, it is possible to further improve the transmission characteristic. For example, in the case where the conductive optical device is used as a touch panel, a plurality of the structural elements may be formed on the surface which becomes a touch side or the surface of the side which is attached on the display apparatus. By doing so, it is possible to improve the reflection preventing characteristic and the transmission characteristic of the touch panel.

As described above, according to the present disclosure, it is possible to realize a conductive optical device capable of securing low resistance and high transmittance and maintaining conductivity with respect to bending.

Additional features and advantages are described herein, and will be apparent from the following Detailed Description and the figures.

### BRIEF DESCRIPTION OF THE FIGURES

FIG. 1A is a schematic plan diagram illustrating an example of a configuration of a conductive optical device according to a first embodiment of the present disclosure.

FIG. 1B is a cross-sectional diagram of the conductive optical device taken along line IB-IB illustrated in FIG. 1A.

FIG. 1C is a partially enlarged perspective diagram of the conductive optical device illustrated in FIG. 1A.

FIG. 2A is a partially enlarged plan diagram of the conductive optical device illustrated in FIG. 1A.

FIG. 2B is a plan diagram illustrating an example where structural elements are arranged so as to form a square lattice pattern or a quasi-square lattice pattern.

FIG. 2C is a plan diagram illustrating an example where the structural elements are arranged so as to meander.

FIGS. 3A to 3C are plan diagrams illustrating examples of other configurations of the arrangement of the structural elements.

FIG. 4 is a schematic diagram illustrating an example of a configuration of a roll master disc exposing apparatus.

FIGS. 5A to 5D are process diagrams illustrating an example of a method of manufacturing the conductive optical device according to the first embodiment of the present disclosure.

FIGS. 6A to 6D are process diagrams illustrating an example of a method of manufacturing the conductive optical device according to the first embodiment of the present disclosure.

FIG. 7A is a perspective diagram illustrating an example of a configuration of a touch panel according to a second embodiment of the present disclosure.

FIG. 7B is a cross-sectional diagram illustrating the example of the configuration of the touch panel according to the second embodiment of the present disclosure.

FIG. 8A is a perspective diagram illustrating a first modified example of a touch panel according to a first modified example of the second embodiment.

FIG. 8B is a fragmented perspective diagram illustrating an example of a configuration of a first conductive optical device.

FIG. 8C is a schematic cross-sectional diagram taken along line VIIIC-VIIIC of FIG. 8B.

FIG. 9A is a perspective diagram illustrating an example of a configuration of a touch panel according to a second modified example of the second embodiment.

FIG. 9B is a cross-sectional diagram illustrating the example of the configuration of the touch panel according to the second modified example of the second embodiment.

FIG. 10A is a perspective diagram illustrating an example of a configuration of a touch panel according to a third modified example of the second embodiment.

FIG. 10B is a cross-sectional diagram taken along line XA-XA of FIG. 10A.

FIG. 11 is a schematic cross-sectional diagram illustrating an example of a configuration of a display apparatus according to a third embodiment of the present disclosure.

FIG. 12A is a schematic perspective diagram illustrating an example of a configuration of an electrochemical device according to a fourth embodiment of the present disclosure.

FIG. 12B is a cross-sectional diagram taken along line XIIB-XIIB of FIG. 12A.

FIG. 13 is a graph illustrating resistance change rates of conductive optical devices of samples 1-1 to 1-3, a sample 2-1, and a sample 3-1.

### DETAILED DESCRIPTION

Embodiments of the present application will be described below in detail with reference to the drawings in the following order.

1. First Embodiment

2. Second Embodiment (Application Example of Information Input Apparatus (Touch Panel))

3. Third Embodiment (Application Example of Display Apparatus (Electronic Paper))

4. Fourth Embodiment (Application Example of electrochemical device (dye-sensitized solar cell))

### 1. First Embodiment

### Configuration of Conductive Optical Device

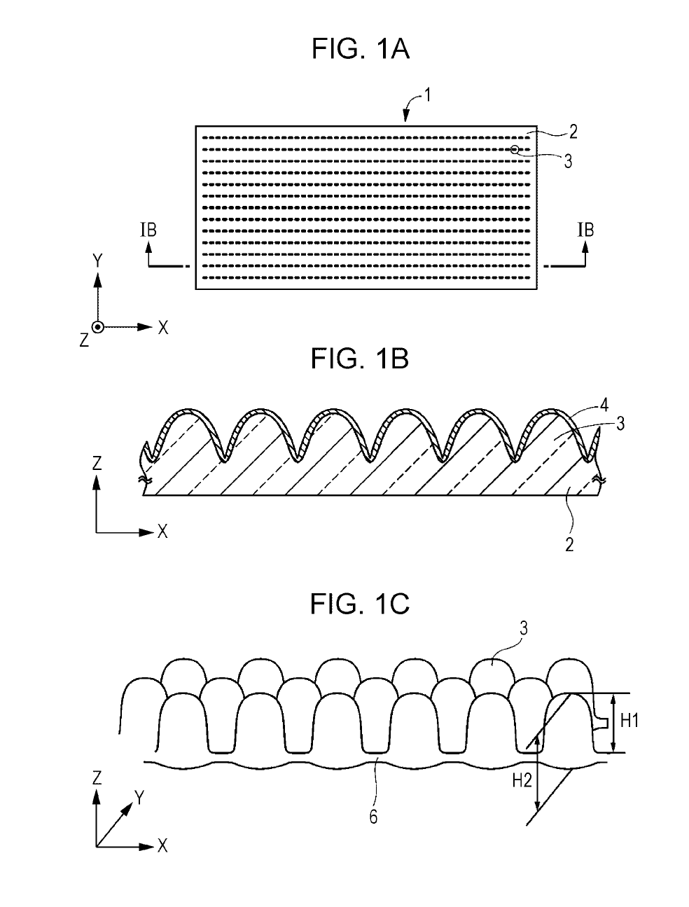

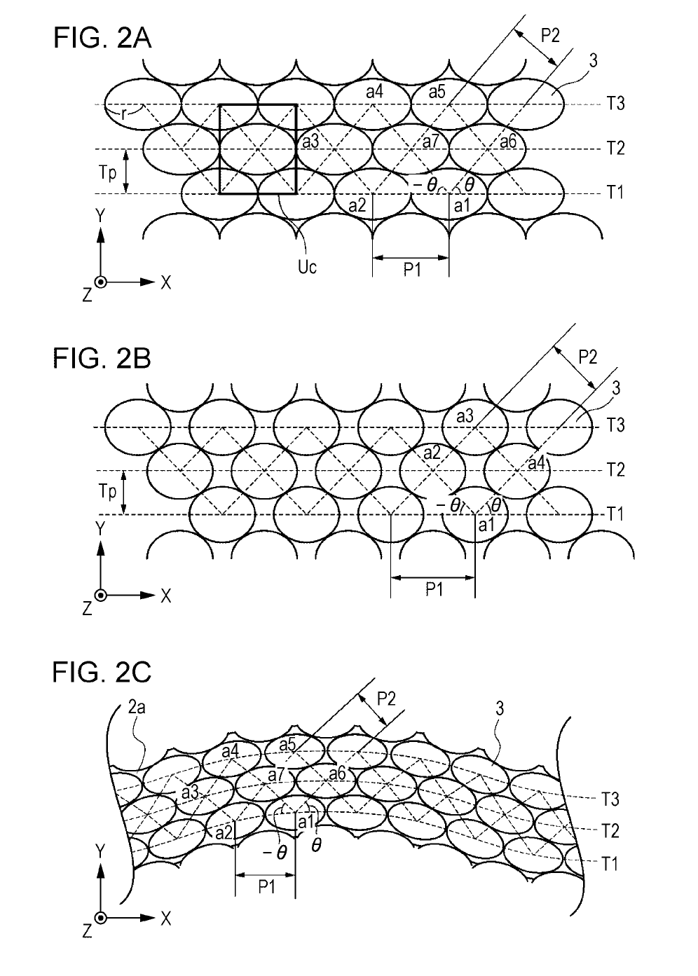

FIG. 1A is a schematic plan diagram illustrating an example of a configuration of a conductive optical device according to a first embodiment of the present disclosure. FIG. 1B is a cross-sectional diagram of the conductive optical device taken along line IB-IB illustrated in FIG. 1A. FIG. 1C is a partially enlarged perspective diagram of the conductive optical device illustrated in FIG. 1A. FIG. 2A is a partially enlarged plan diagram of the conductive optical device illustrated in FIG. 1A. FIG. 2B is a plan diagram illustrating an example where structural elements are arranged so as to form a square lattice pattern or quasi-square lattice pattern. FIG. 2C is a plan diagram illustrating an example where the structural elements are arranged so as to meander. Hereinafter, two perpendicular directions in a surface of the conductive optical device are set to an X axis direction and Y axis direction, and the direction vertical to the X axis direction and the Y axis direction is referred to as a Z axis direction.

The conductive optical device includes a substrate having flexibility, a plurality of the structural elements constructed with convex portions or concave portions which are arranged on one main surface with a fine pitch which is equal to or less than a wavelength of light for reducing reflection, and a transparent conductive layer formed on the structural elements. The conductive optical device has a function of preventing reflection of the light transmitting in the −Z direction of FIGS. 1A to 1C on the interface of the structural elements and the ambient air.

As illustrated in FIGS. 1A to 1C, the conductive optical device 1 according to the first embodiment includes a substrate 2 having a surface where a plurality of the structural elements 3 are arranged and a transparent conductive layer 4 formed on the structural elements 3. The aspect ratio of the structural elements 3 is set to be equal to or more than 0.1 and equal to or less than 1.8, and the transparent conductive layer 4 has a surface emulating the structural elements 3. Since the transparent conductive layer 4 is formed on the structural elements 3 of which the aspect ratio is equal to or more than 0.1 and equal to or less than 1.8, the conductivity of the conductive optical device 1 is maintained with respect to the bending test.

Hereinafter, the substrate 2, the structural elements 3, and the transparent conductive layer 4 which may be included in the conductive optical device 1 will be described sequentially.

(Substrate)

The substrate 2 is, for example, a transparent substrate having transparency. Materials of the substrate 2 include, for example, a plastic material having a transparency, glass, and the like as main components. However, the materials of the substrate 2 are not particularly limited thereto. In terms of optical characteristics such as transparency, refractive index, and dispersion and other characteristics such as impact resistance, heat resistance, and durability, the plastic material preferably includes polymethyl methacrylate, (meth) acrylic resins such as copolymers of vinyl monomers such as methyl methacrylate, other alkyl (meth)acrylates, and styrene; polycarbonate resins such as polycarbonate and diethylene glycol bis(allyl carbonate) (CR-39); thermosetting (meth)acrylic resins such as homopolymers or copolymers of (brominated) bisphenol A-type di(meth)acrylate and polymers and copolymers of urethane modified monomers of (brominated) bisphenol A mono(meth)acrylate; polyesters, particularly, polyethylene terephthalate, polyethylene naphthalate, and unsaturated polyester, acrylonitrile-styrene copolymer, polyvinyl chloride, polyurethane, epoxy resins, polyarylate, polyether sulfone, polyether ketone, cycloolefin polymer (trade name: ARTON, ZEONOR), and the like. In addition, in terms of the heat resistance, aramid resins may also be used. In the case where the main component of the substrate 2 is glass, it is preferable that the substrate 2 have a thickness so that the substrate 2 has flexibility, for example, a thickness of about 50 μm to about 100 μm.

In the case where the substrate 2 is a plastic film, the substrate 2 may be obtained for example, by a method of extracting the aforementioned resin, a method of lengthening the aforementioned resin, a cast molding method of diluting the aforementioned resin with a solvent, forming a layer thereof on a film, and drying, or the like. In addition, the thickness of the substrate 2 is, for example, in a range of about 25 μm to about 500 μm.

In the case where the plastic material is used as the substrate 2, an undercoat layer may be prepared through surface treatment in order to further improve surface energy, coating properties, smoothness, flatness, and the like of the surface of the plastic material. The undercoat layer includes, for example, an organo alkoxy metal compound, polyester, acrylic-modified polyester, polyurethane, or the like. In addition, in order to obtain the same effect as that of the preparation of the undercoat layer, corona discharge, UV (Ultraviolet) illumination treatment, or the like may also be performed on the surface of the substrate 2.

The shape of the substrate 2 includes, for example, a sheet shape, a plate shape, and a block shape, but the shape of the substrate 2 is not particularly limited to the aforementioned shapes. Herein, it may be defined that the sheet includes a film. It is preferable that the shape of the substrate 2 be appropriately selected according to a shape or the like of a portion in which a predetermined reflection preventing function is necessary in an optical apparatus or the like such as a camera.

(Structural Element)

A plurality of the structural elements 3 which are convex portions are arranged on the surface of the substrate 2. The structural elements 3 are periodically arranged two-dimensionally with a short arrangement pitch which is equal to or less than the wavelength band of the light for reducing reflection, for example, with the arrangement pitch which is substantially the same as the wavelength of visible light. Herein, the arrangement pitch denotes the arrangement pitch P1 and the arrangement pitch P2 illustrated in FIGS. 2A to 2C. The wavelength band of the light for reducing reflection is, for example, the wavelength band of ultraviolet light, the wavelength band of visible light, or the wavelength band of infrared light. Herein, the wavelength band of ultraviolet light is the wavelength band of 10 nm to 360 nm; the wavelength band of visible light is the wavelength band of 360 nm to 830 nm; and the wavelength band of infrared light is the wavelength band of 830 nm to 1 mm. More specifically, the arrangement pitch is, preferably, equal to or more than 180 nm and equal to or less than 350 nm, more preferably, equal to or more than 190 nm and equal to or less than 280 nm. If the arrangement pitch is less than 180 nm, there is a tendency in that it is difficult to manufacture the structural elements 3. On the other hand, if the arrangement pitch exceeds 350 nm, there is a tendency in that diffraction of visible light occurs.

As illustrated in FIGS. 2A to 2C, the structural elements 3 are arranged so as to form, for example, a plurality of columns of the tracks T1, T2, T3, . . . (hereinafter, collectively referred to as “track T”). As illustrated in FIG. 2A, P1 indicates the arrangement pitch of the structural elements 3 (distance between a1 and a2) in the same track (for example, T1). P2 indicates the arrangement pitch of the structural elements 3 of the two adjacent tracks (for example, T1 and T2), that is, the arrangement pitch of the structural elements 3 (for example, distance between a1 and a7 or distance between a2 and a7) in the ±θ direction with respect to the track extension direction. In the present disclosure, the track denotes a portion where the structural elements 3 form a column to be aligned in a straight line shape or a curved line shape. In addition, the column direction denotes a direction perpendicular to the track extension direction (for example, X axis direction) on the surface of the substrate 2 where a group of the structural elements 3 is formed.

In the example illustrated in FIG. 2A, the structural elements 3 between the two adjacent tracks T are arranged, for example, at half-pitch shifted positions. More specifically, between the two adjacent tracks T, the structural elements 3 of the other track (for example, T2) are arranged at the intermediate positions (half-pitch shifted positions) among the structural elements 3 which are arranged in the one track (for example, T1). As a result, as illustrated in FIG. 2A, the structural elements 3 are arranged so as to form a hexagonal lattice pattern or a quasi-hexagonal lattice pattern where the centers of the structural elements 3 are located at the points a1 to a7 among the three adjacent columns of the tracks (T1 to T3). In an embodiment, the hexagonal lattice pattern denotes a regular hexagonal shaped lattice pattern. In addition, unlike the regular hexagonal shaped lattice pattern, the quasi-hexagonal lattice pattern denotes a deformed hexagonal lattice pattern which is enlarged in the track extension direction (for example, the X axis direction).

In the case where the structural elements 3 are arranged so as to form a quasi-hexagonal lattice pattern, as illustrated in FIG. 2A, it is preferable that the arrangement pitch P1 of the structural elements 3 in the same track (for example, T1) is larger than the arrangement pitch of the structural elements 3 between the two adjacent tracks (for example, T1 and T2), that is, the arrangement pitch P2 of the structural elements 3 in the ±θ direction with respect to the track extension direction. The structural elements 3 are arranged in this manner, so that it is possible to further increase the packing density of the structural elements 3.

In the example illustrated in FIG. 2B, the structural elements 3 form a square lattice pattern or a quasi-square lattice pattern among the three adjacent columns of the tracks. Herein, unlike the regular square lattice pattern, the quasi-square lattice pattern denotes a deformed square lattice pattern which is enlarged in the track extension direction (X direction).

In the example illustrated in FIG. 2C, the structural elements 3 are arranged in a meandering track (hereinafter, referred to a wobble track). It is preferable that the wobbles of the tracks on the substrate 2 be synchronized with each other. In other words, it is preferable that the wobble be a synchronized wobble. In this manner, the wobbles are synchronized with each other, so that it is possible to maintain the unit lattice shape of the hexagonal lattice or the quasi-hexagonal lattice. As a waveform of the wobble track, for example, a sinusoidal waveform, a triangular waveform, or the like may be exemplified. The waveform of the wobble track is not limited to a periodic waveform, and a non-periodic waveform may be used. A wobble amplitude of the wobble track is selected to be, for example, about ±10 μm.

In addition, in the case where the structural elements are arranged to meander, the quasi-hexagonal lattice denotes a hexagonal lattice formed by deforming the regular hexagonal shaped lattice by the meandering arrangement of the structural elements. In addition, the quasi-hexagonal lattice may denote a hexagonal lattice formed by extending the regular hexagonal shaped lattice in the straight line shaped arrangement direction (track direction) to be deformed and by deforming the regular hexagonal shaped lattice by the meandering arrangement of the structural elements. The quasi-square lattice denotes a square lattice formed by deforming the regular square shaped lattice by the meandering arrangement of the structural elements. In addition, the quasi-square lattice may denote a square lattice formed by extending the regular square shaped lattice in the straight line shaped arrangement direction (track direction) to be deformed and by deforming the regular square shaped lattice by the meandering arrangement of the structural elements.

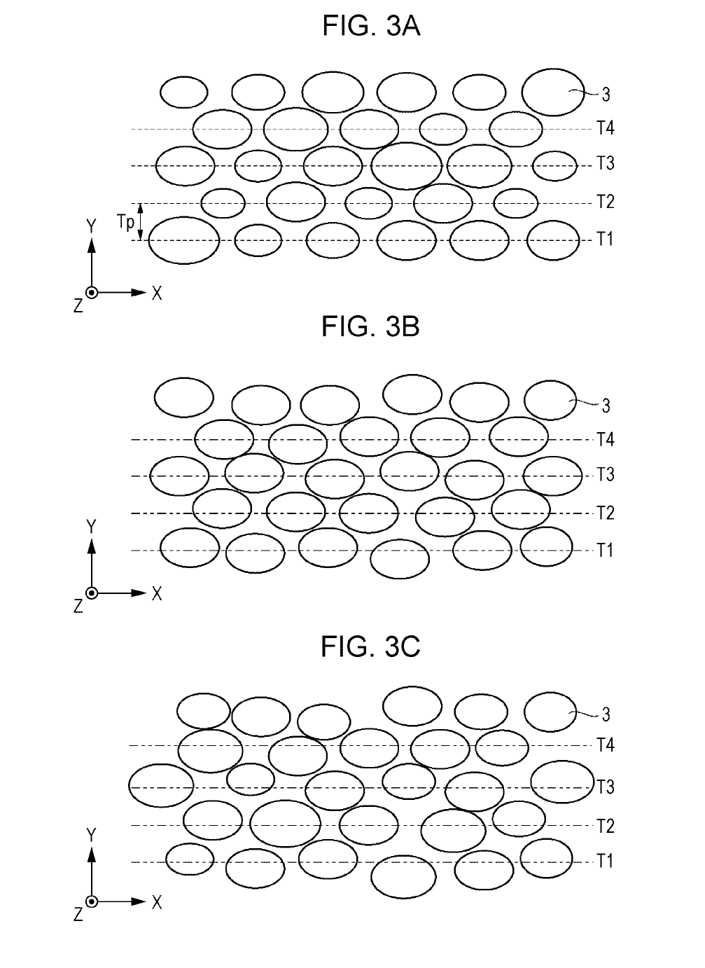

FIGS. 3A to 3C are plan diagrams illustrating examples of other configurations of the arrangement of the structural elements. As illustrated in FIG. 3A, the sizes of the structural elements 3 formed on the surface of the substrate 2 may be set at random; and as illustrated in FIG. 3B, the arrangement of the structural elements 3 formed on the surface of the substrate 2 may be set at random. In addition, as illustrated in FIG. 3C, the size and arrangement of the structural elements 3 formed the surface of the substrate 2 may be set at random.

As a specified shape of the structural elements 3, for example, a cone shape, a columnar shape, a needle shape, a hemispheric shape, a spherical semi-elliptical shape, a polygonal shape, and the like may be exemplified. However, it is not limited to the aforementioned shapes, and other shapes may be employed. In addition, a shape where a top portion is cut off may be employed, and a fine hole may be formed on a surface of the structural element 3, for example, a top portion.

In terms of forming ease, it is preferable that the structural element 3 have a cone shape or a cone shape formed by extending or contracting the cone shape in the track direction. It is preferable that the structural element 3 have an axial symmetric cone shape or a cone shape formed by extending or contracting the cone shape in the track direction. In the case where the structural element 3 is attached to the adjacent structural elements 3, it is preferable that the structural element 3 have an axial symmetric cone shape excluding the lower portion attached to the adjacent structural elements 3 or a cone shape formed by extending or contracting the cone shape in the track direction. As a cone shape, for example, a conical shape, a truncated conical shape, an elliptical cone shape, a truncated elliptical cone shape, and the like may be exemplified. Herein, as described above, the cone shape also includes an elliptical cone shape and a truncated elliptical cone shape as well as the conical shape and the truncated conical shape. In addition, the truncated conical shape denotes a shape formed by cutting off the top portion of the conical shape, and the truncated elliptical cone shape denotes a shape by cutting off the top portion of the elliptical cone shape.

It is preferable that the structural element 3 have a cone shape having a bottom surface of which the width in the track extension direction is larger than the width in the column direction perpendicular to the extension direction. More specifically, it is preferable that the structural element 3 have an elliptical cone shape of which the top portion is a curved surface as a conical structure of which the bottom surface has an elliptic shape, an oval shape, or an egg-like shape having the longest axis and the shortest axis. This is because, if the structural element 3 has these shapes, it is possible to improve the packing ratio in the column direction.

In addition, in the example illustrated in FIG. 1C, although the structural elements 3 have the same size and/or shape, the shape of the structural elements 3 is not limited thereto. The structural elements 3 having sizes and/or shapes of two or more may be formed so as to be mixed. In the case where a roll master disc is manufactured by using the later-described roll master disc exposing apparatus, it is preferable that an elliptical cone shape of which the top portion has a convex curved surface or a truncated elliptical cone shape of which the top portion is flat be employed as the shape of the structural element 3, and the direction of the longest axis of the elliptic shape of the bottom surface be coincident with the track extension direction.

In terms of improvement of the reflection characteristic, a cone shape (refer to FIG. 1C) where the slope of the information is gentle and the slope from the central portion to the bottom portion is gradually steepened is preferred. In addition, in terms of improvement of the reflection characteristic and the transmission characteristic, a conical shape where the slope of the central portion is steeper than those of the bottom portion and the top portion or a cone shape where the top portion is flat is preferred. In the case where the structural element 3 has an elliptical cone shape or a truncated elliptical cone shape, it is preferable that the direction of the longest axis of the bottom surface be parallel to the track extension direction.

In addition, as illustrated in FIG. 1C, it is preferable that protrusions 6 are prepared in a portion of or the entire circumference of the structural element 3. This is because, by doing so, even in the case where the packing ratio of the structural elements 3 is low, the reflectance may be suppressed to be low. More specifically, for example, as illustrated in FIG. 1C, the protrusion 6 is disposed between the adjacent structural elements 3. In addition, an elongated protrusion 6 may be disposed in a portion of or the entire circumference of the structural element 3. The elongated protrusion 6 is extended, for example, in the direction from the top portion of the structural element 3 to the lower portion thereof. The shape of the protrusion 6 includes a cross-sectional triangular shape, a cross-sectional rectangular shape, and the like. However, the shape of the protrusion 6 is not particularly limited thereto, and it may be selected by considering ease of forming, or the like. In addition, fine convex-concave portions may be formed by roughening the surface of a portion of or the entire circumference of the structural element 3. More specifically, the fine convex-concave portions may be formed by roughening the surface, for example, between the adjacent structural elements 3.

In terms of peeling of the structural elements 3 from a mold or the like in a process of manufacturing the conductive optical device 1, it is preferable that an edge portion be prepared in the circumferential portion of the structural element 3. Herein, the edge portion denotes a protrusion disposed in the circumferential portion of the bottom portion of the structural element 3. In terms of the peeling characteristic, it is preferable that the edge portion have a curved surface of which the height is gently decreased in the direction from the top portion of the structural element 3 to the lower portion thereof. In addition, although the edge portion may be disposed in a portion of the circumferential portion of the structural element 3, in terms of improvement of the peeling characteristic, it is preferable that the edge portion be disposed in the entire circumferential portion of the structural element 3. In addition, the structural element 3 is not limited to the illustrated shape of the convex portion, but it may be configured by a concave portion formed on the surface of the substrate 2. In the case where the structural element 3 is a concave portion, the edge portion becomes a curved surface which is disposed in the circumferential portion of opening of the concave portion which is the structural element 3.

It is preferable that the height H1 of the structural element 3 in the track extension direction be smaller than the height H2 of the structural element 3 in the column direction. In other words, it is preferable that the heights H1 and H2 of the structural element 3 satisfy the relationship of H1<H2. This is because, if the structural elements 3 are arranged so as to satisfy H1≧H2, it is necessary to enlarge the arrangement pitch P1 in the track extension direction, such that the packing ratio of the structural elements 3 in the track extension direction is lowered. In this manner, if the packing ratio is lowered, the reflection characteristic deteriorates.

It is preferable that the aspect ratio of the structural elements 3 (average height/average arrangement pitch) be set to in a range of equal to or more than 0.1 and equal to or less than 1.8. This is because the conductivity of the conductive optical device 1 may be maintained with respect to the bending test. In addition, if the aspect ratio exceeds 1.8, the peeling characteristic of the structural elements 3 during the manufacturing of the conductive optical device 1 deteriorates, and there is a tendency that the replica is clearly copied.

The average arrangement pitch and the average height may be obtained as follows. The conductive optical device 1 is cut so as to include the top portion of the structural element 3. The cross section is photographed by a transmission electron microscope (TEM). Next, the arrangement pitch of the structural elements 3 (the arrangement pitch P1 or P2 illustrated in FIGS. 2A to 2C) and the height of the structural element 3 (the height difference between the top portion and the valley portion of the convex-concave shape of the cross section) are obtained from the photographed TEM picture. This measurement is repetitively performed on 10 sites which are selected from the conductive optical device 1 at random. The average arrangement pitch and the average height are obtained by simply averaging the measured values p1, p2, . . . p10 and averaging the measured values h1, h2, . . . h10, respectively (arithmetical average). In other words, the average arrangement pitch and the average height are defined by the relationships expressed by the following Equations (1) and (2), respectively.

(Average Arrangement Pitch)=(p1+p2+ . . . +p10)/10 (1)

(Average Height)=(h1+h2+ . . . +h10)/10 (2)

Herein, P1: the arrangement pitch in the track extension direction, H1: the height of the structural element in the track extension direction, P2: the arrangement pitch in the ±ξ direction (herein, θ=60°−δ, and δ is preferably 0°<δ≦11°, more preferably) 3°≦δ≦6°) with respect to the track extension direction, and H2: the height of the structural element in the ±θ direction with respect to the track extension direction. In the case where the structural element 3 is a concave portion, in the above Equation (2), the height of the structural element is replaced with the depth of the structural element.

In addition, the present disclosure is not limited to the case where all the aspect ratios of the structural elements 3 are the same, but the structural elements 3 may be configured so as to have a constant height distribution in a range of equal to or more than 0.1 and equal to or less than 1.8. The structural elements 3 having a height distribution are disposed, so that the wavelength dependency of the reflection characteristic may be reduced. Therefore, it is possible to implement the conductive optical device 1 having an excellent reflection preventing characteristic.

Herein, the height distribution denotes that the structural elements 3 having two or more types of heights (depths) are disposed on the surface of the substrate 2. In other words, this denotes that the structural elements 3 having a reference height and the structural elements 3 having a height different from the reference height of the structural elements 3 are disposed on the surface of the substrate 2. The structural elements 3 having a height different from the reference height are disposed, for example, on the surface of the substrate 2 periodically or non-periodically (at random). The direction of the periodicity may be, for example, the track extension direction, the column direction, or the like.

When the arrangement pitch of the structural elements 3 in the same track is denoted by P1 and The arrangement pitch of the structural elements 3 between the two adjacent tracks is denoted by P2, it preferable that the ratio P1/P2 satisfy a relationship of 1.00≦P1/P2≦1.1 or 1.00<P1/P2≦1.1. In this numerical range, since the packing ratio of the structural elements 3 having an elliptical cone shape or a truncated elliptical cone shape may be improved, it is possible to improve the reflection preventing characteristic.

The packing ratio of the structural elements 3 on the surface of the substrate is in a range of equal to or more than 65%, preferably, equal to or more than 73%, more preferably equal to or more than 86% as the upper limit is 100%. By setting the packing ratio to be in the range, it is possible to improve the reflection preventing characteristic. In order to improve the packing ratio, it is preferable that the lower portions of the adjacent structural elements 3 are allowed to be attached, or the structural element 3 be deformed through the adjustment or the like of the ellipticity of the bottom surface of the structural element. Herein, when the diameter of the bottom surface of the structural element in the track direction (X direction) is denoted by a, and the diameter in the column direction (Y direction) perpendicular to the track direction is denoted by b, the ellipticity is defined by (a/b)×100. In addition, the diameters a and b of the structural element 3 are the values obtained as follows. The surface of the conductive optical device 1 is photographed in a top view by a scanning electron microscope (SEM), and 10 structural elements 3 are extracted from the photographed SEM picture at random. Next, the diameters a and b of the bottom surface of each of the extracted structural elements 3 are measured. Next, the average values of the diameters a and b are obtained by simply averaging the measured values a and b (arithmetical average), and the average values are set to the diameters a and b of the structural elements 3.

Herein, the packing ratio of the structural elements 3 (average packing ratio) is the value obtained as follows.

First, the surface of the conductive optical device 1 is photographed in a top view by a scanning electron microscope (SEM). Next, the unit lattices Uc are selected from the photographed SEM picture at random, and the arrangement pitch P1 of the unit lattices Uc and the track pitch Tp are measured (refer to FIG. 1A). In addition, the area S of the bottom surface of the structural element 3 which is located at the center of the unit lattice Uc is measured through an image process. Next, the packing ratio is obtained from the following Equation (3) by using the measured arrangement pitch P1, track pitch Tp, and area S of the bottom surface.

Packing Ratio=(S(hex.)/S(unit))×100 (3)

Area of Unit Lattice: S (unit)=P1×2Tp

Area of Bottom Surface of Structural Element Present in Unit Lattice: S (hex.)=2S

The aforementioned packing ratio calculation process is performed on the unit lattices of the 10 sites selected from the photographed SEM picture at random. Next, the average value of the packing ratios is obtained by simply averaging the measured values (arithmetical average), and the average value is set to the packing ratio of the structural elements 3.

With respect to the packing ratio of the case where the structural elements 3 are overlapped or the case where sub structural elements such as the protrusions 6 are present between the structural elements 3, the packing ratio may be obtained by a method of determining an area ratio by using a portion corresponding to the height of the structural elements 3 which is 5% of the height of the structural element as a threshold value.

A ratio ((2r/P1)×100) of the diameter 2r to the arrangement pitch P1 is equal to or more than 85%, preferably equal to or more than 90%, more preferably equal to or more than 95%. This is because the packing ratio of the structural elements 3 may be improved in this range, so that it is possible to improve the reflection preventing characteristic. As the ratio ((2r/P1)×100) increases, if the overlapping of the structural elements 3 increases too much, there is a tendency in that the reflection preventing characteristic deteriorates. Therefore, it is preferable that the upper limit value of the ratio ((2r/P1)×100) is set so that the structural elements are attached to each other in a portion where the maximum value of the wavelength band of light under the use environment with an optical path length considering the refractive index is equal to or less than ¼. Herein, the arrangement pitch P1 is the arrangement pitch of the structural elements 3 in the track direction, and the diameter 2r is the diameter of the bottom surface of the structural element in the track direction. In addition, in the case where the bottom surface of the structural element has a circular shape, the diameter 2r is the diameter; and in the case where the bottom surface of the structural element has an elliptic shape, the diameter 2r is the longest axis.

(Transparent Conductive Layer)

it is preferable that the transparent conductive layer 4 include a transparent oxide semiconductor as a main component. As the transparent oxide semiconductor, for example, two-element compounds such as SnO₂, InO₂, ZnO, and CdO, three-element compounds including at least one element among the constituent elements such as Sn, In, Zn, and Cd, or multi-element (complex) oxide may be used. As a material constituting the transparent conductive layer 4, for example, ITO (In₂O₃, SnO₂: indium tine oxide), AZO (Al₂O₃, ZnO: aluminum doped zinc oxide), SZO, FTO (fluorine doped tin oxide), SnO₂ (tin oxide), GZO (gallium doped zinc oxide), IZO (In₂O₃, ZnO: zinc indium oxide), and the like may be exemplified. In terms of high reliability and low resistivity, the ITO is preferred. In terms of improvement of the conductivity, it is preferable that the material constituting the transparent conductive layer 4 be in a state where amorphous material and polycrystalline material are mixed. The transparent conductive layer 4 is formed by emulating the surface shape of the structural element 3, and preferably, the surface shapes of the structural element 3 and the transparent conductive layer 4 are substantially similar to each other. This is because it is possible to maintain an excellent reflection preventing characteristic and/or transmission characteristic by suppressing a change of the refractive index profile due to the formation of the transparent conductive layer 4.

It is preferable that the thickness of the transparent conductive layer 4 in the top portion of the structural element is in a range of equal to or more than 5 nm and equal to or less than 150 nm. At this time, by setting the aspect ratio of the structural elements 3 to be in a range of equal to or more than 0.1 and equal to or less than 1.8, when the thickness of the transparent conductive layer 4 in the top portion of the structural element is set to be in a range of equal to or more than 5 nm and equal to or less than 150 nm, it is possible to maintain the conductivity of the conductive optical device 1 with respect to the bending test. In other words, if the aspect ratio and the thickness of the transparent conductive layer 4 in the top portion of the structural elements satisfy the aforementioned numerical range, it is possible to obtain the surface resistance which is in a range of, for example, equal to or more than 50Ω/and less than 500Ω/and to simultaneously implement the bendability, the low resistance, and the high transmittance of the transparent conductive film.

It is preferable that the surface resistance of the transparent conductive layer 4 be in a range of equal to or more than 50Ω/and less than 500Ω/. This is because, by setting the surface resistance to be in this range, the transparent conductive optical device 1 may be used as the upper electrode or the lower electrode of various types of touch panels. Herein, the surface resistance of the transparent conductive layer 4 is obtained through 4-terminal measurement (JIS K 7194).

[Method of Manufacturing Conductive Optical Device]

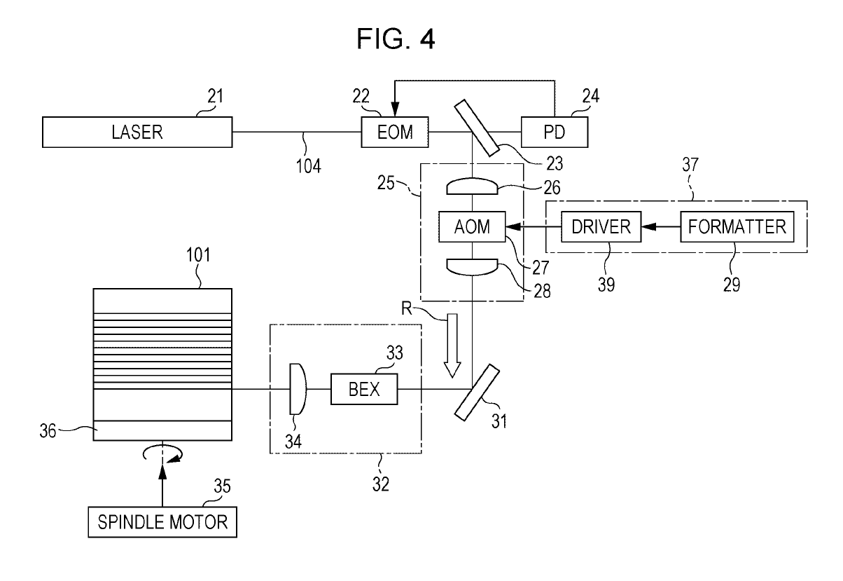

Next, an example of a method of manufacturing the conductive optical device 1 having the aforementioned configuration is described with reference to FIGS. 4 to 6.

[Configuration of Roll Master Disc Exposing Apparatus]

First, a configuration of a roll master disc exposing apparatus for manufacturing a roll master disc will be described with reference to FIG. 4. The roll master disc exposing apparatus is configured by using an optical disc recording apparatus as a base.

The roll master disc 101 is, for example, a master disc having a cylindrical shape. The roll master disc 101 has a transfer surface Sp formed on the surface thereof. For example, a plurality of the structural elements 103 having a concave shape or a convex shape are formed on the transfer surface Sp, and the shapes of the structural elements 103 are transferred to the energy beam curable resin composition 118 coated on the substrate 102, so that a shape layer 30 having the structural elements 3 of the conductive optical device 1 is formed. In other words, the pattern where the convex-concave shape of the structural elements 3 of the conductive optical device 1 is inverted is formed on the transfer surface Sp.

As a material of the roll master disc 101, for example, metal, glass, quartz, transparent resins, organic-inorganic hybrid materials, or the like may be used, but it is not particularly limited. As a transparent resin, for example, polymethyl methacrylate (PMMA), polycarbonate (PC), and the like may be exemplified. As an organic-inorganic hybrid material, for example, polydimethylsiloxane (PDMS) and the like may be exemplified.

FIG. 4 is a schematic diagram illustrating an example of a configuration of a roll master disc exposing apparatus for manufacturing a roll master disc. The roll master disc exposing apparatus is configured by using an optical disc recording apparatus as a base.

The laser light source 21 is a light source for exposing the resist attached as a film on the surface of the roll master disc 101 as a recording medium to oscillate the recording laser light 104 having a wavelength λ of, for example, 266 nm. The laser light 104 emitted from the laser light source 21 propagates straightly as a parallel beam to be incident on the electro-optical device (EOM: Electro Optical Modulator) 22. The laser light 104 transmitting the electro-optical device 22 is reflected on the mirror 23 to be guided into the modulation optic system 25.

The mirror 23 is constructed with a polarization beam splitter and has a function of reflecting one polarization component and transmitting the other the polarization component. The polarization component transmitting the mirror 23 is received by a photodiode 24, and the phase modulation of the laser light 104 is performed by controlling the electro-optical device 22 based on the light receiving signal.

In the modulation optic system 25, the laser light 104 is collected on the acoustic optical device (AOM: Acoustic-Optic Modulator) 27 constructed with glass (SiO₂) or the like by the collecting lens 26. The laser light 104 is subject to the intensity modulation by the acoustic optical device 27 and diverges, and thereafter, the laser light 104 is changed into a parallel beam by the lens 28. The laser light 104 emitted from the modulation optic system 25 is reflected by the mirror 31 to be guided onto the movable optic table 32 horizontally or in parallel.

The movable optic table 32 includes a beam expander 33 and an objective lens 34. The laser light 104 guided onto the movable optic table 32 is shaped into a desired beam shape by the beam expander 33, and thereafter, the resist layer on the roll master disc 101 is illuminated with the laser light 104 through the objective lens 34. The roll master disc 101 is mounted on a turntable 36 connected to a spindle motor 35. Next, while the roll master disc 101 is rotated, the laser light 104 is moved in the height direction of the roll master disc 101, and the resist layer is intermittently illuminated with the laser light 104, so that the exposing process is performed on the resist layer. The formed latent image has a substantially elliptic shape having the longest axis in the circumferential direction. The movement of the laser light 104 is performed by moving the movable optic table 32 in the arrow R direction.

The exposing apparatus includes, for example, a control mechanism 37 for forming a latent image corresponding to a two-dimensional pattern such as a hexagonal lattice or a quasi-hexagonal lattice illustrated in FIG. 2A on the resist layer. The control mechanism 37 includes a formatter 29 and a driver 39. The formatter 29 includes a polarity conversion unit, and the polarity conversion unit controls a timing of illumination of the laser light 104 on the resist layer. The driver 39 receives an output of the polarity conversion unit and controls the acoustic optical device 27.

In the roll master disc exposing apparatus, the signal for synchronizing the polarity conversion formatter signal and the controller of the recording apparatus in each track is generated so that two-dimensional pattern is linked spatially, and the intensity modulation is performed by the acoustic optical device 27. The patterning is performed at a constant angular velocity (CAV), with an appropriate number of rotations, an appropriate modulation frequency, and an appropriate transport pitch, so that a hexagonal lattice pattern or a quasi-hexagonal lattice pattern may be recorded. For example, in order to set the period in the circumferential direction to 315 nm and to set the period in the about 60° direction (about −60° direction) with respect to the circumferential direction to 300 nm, the transport pitch may be set to 251 nm (Pythagoras' theorem). The frequency of the polarity conversion formatter signal is changed according to the number of rotations of the roll (for example, 1800 rpm, 900 rpm, 450 rpm, or 225 rpm). For example, the frequencies of the polarity conversion formatter signal corresponding to the numbers of rotation of the roll which are 1800 rpm, 900 rpm, 450 rpm, and 225 rpm become 37.70 MHz, 18.85 MHz, 9.34 MHz, and 4.71 MHz. The quasi-hexagonal lattice pattern where the spatial frequency (a period of 315 nm in the circumferential direction, a period of 300 nm in the about 60° direction (about −60° direction) of the circumferential direction) is constant in a desired recording area maybe obtained by expanding far-ultraviolet light laser light to five times beam diameter by the beam expander (BEX) 33 on the movable optic table 32 and illuminating the resist layer on the roll master disc 101 with the far-ultraviolet light laser light through the objective lens 34 having a numerical aperture (NA) of 0.9 to form a fine latent image.

[Method of Manufacturing Conductive Optical Device]

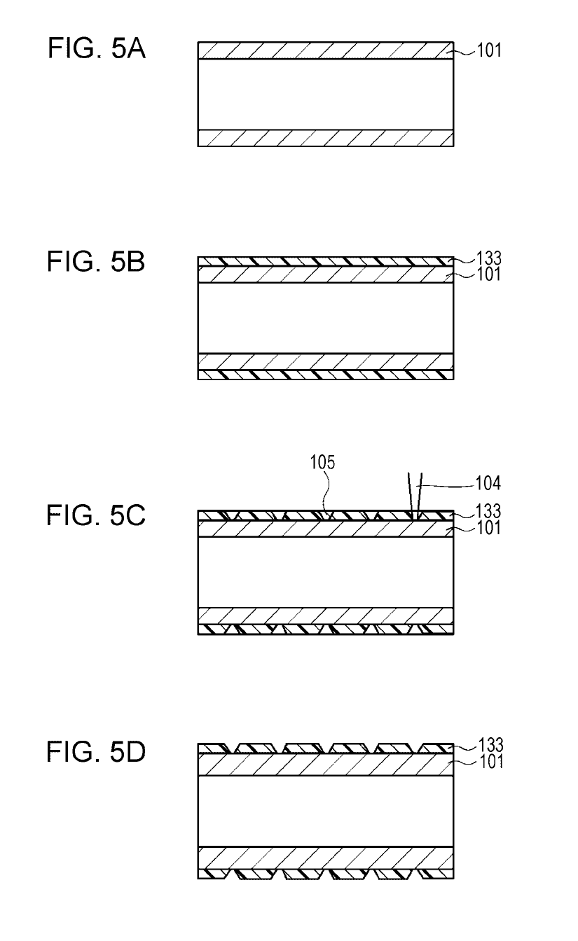

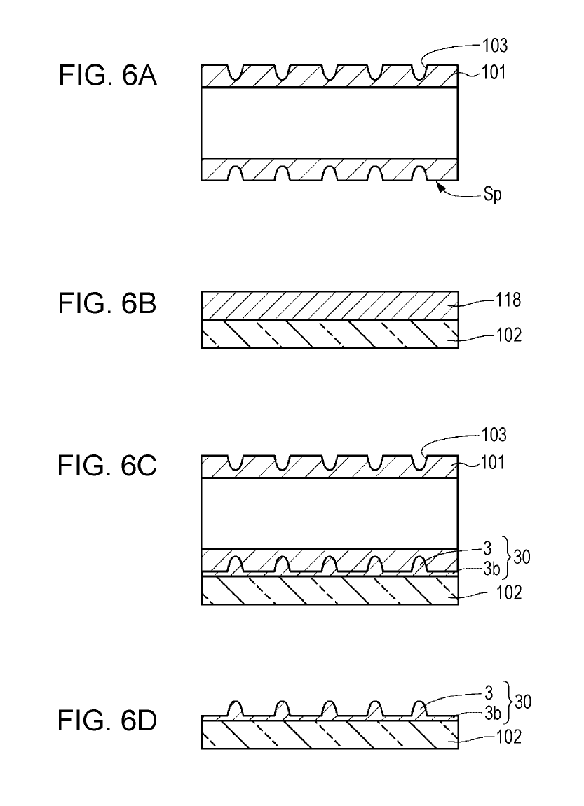

FIGS. 5A to 6D are process diagrams illustrating an example of a method of manufacturing the conductive optical device according to the first embodiment of the present disclosure.

(Resist Film Forming Process)

First, as illustrated in FIG. 5A, the cylindrical roll master disc 101 is prepared. Next, as illustrated in FIG. 5B, a resist layer 133 is formed on the surface of the roll master disc 101. As a material of the resist layer 133, for example, any one of the organic resist and the inorganic resist may be used. As the organic resist, for example, a novolac resist, a chemically-amplified type resist, or the like may be used. In addition, as the inorganic resist, a metal compound which includes, for example, one type or two or more types of transition metals may be used.

(Exposing Process)

Next, as illustrated in FIG. 5C, the resist layer 133 formed on the surface of the roll master disc 101 is illuminated with laser light (exposing beam) 104. More specifically, the roll master disc 101 is mounted on the turntable 36 of the roll master disc exposing apparatus illustrated in FIG. 4 and rotated, and the resist layer 133 is illuminated with the laser light (exposing beam) 104. At this time, while the laser light 104 is moved in the height direction of the roll master disc 101 (the direction parallel to the central shaft of a cylindrical columnar or cylindrical roll master disc 101), the illumination of the laser light 104 is intermittently performed, so that exposure is performed on the entire surface of the resist layer 133. By doing so, a latent image 105 according to the trajectory of the laser light 104 is formed over the entire surface of the resist layer 133 with a pitch which is substantially equal to the wavelength of visible light.

The latent image 105 is disposed to constitute a plurality of columns of tracks, for example, on the surface of the master disc and to form a hexagonal lattice pattern or a quasi-hexagonal lattice pattern. The latent image 105 has, for example, an elliptical shape having the direction of the longest axis in the track extension direction.

(Developing Process)

Next, as illustrated in FIG. 5D, a developing process is performed on the resist layer 133 by dropping a developing solution on the resist layer 133 while rotating the roll master disc 101. As illustrated, in the case where the resist layer 133 is formed by positive type resist, since the dissolution speed of an exposed portion which is exposed to the laser light 104 with respect to the developing solution is increased in comparison with a non-exposed portion, a pattern according to the latent image (exposed portion) 105 is formed on the resist layer 133.

(Etching Process)

Next, an etching process is performed on the surface of the roll master disc 101 by using a pattern (resist pattern) of the resist layer 133 formed on the roll master disc 101 as a mask. By doing so, as illustrated in FIG. 6A, it is possible to obtain the concave portions having an elliptical cone shape or a truncated elliptical cone shape having the direction of the longest axis in the track extension direction, that is, the structural elements 103. As the etching, for example, dry etching or wet etching may be used.

(Transfer Process)

Next, according to necessity, surface treatment such as corona treatment, plasma treatment, flame treatment, UV treatment, ozone treatment, or blasting treatment is applied to the surface of the substrate 102 which is doped with the energy beam curable resin composition 118. Next, as illustrated in FIG. 6C, the energy beam curable resin composition 118 is doped or printed on the elongated substrate 102 or the roll master disc 101. The doping method is not particularly limited, and for example, potting on a substrate or a disc, a spin coating method, a gravure coating method, a die coating method, a bar coating method, or the like may be used. As the printing method, for example, a relief printing method, an offset printing method, a gravure printing method, an intaglio printing method, a rubber plate printing method, a screen printing method, or the like may be used. Next, according to necessity, solvent removal or heat treatment such as pre-baking may be performed.

The energy beam curable resin composition denotes a resin composition which may be cured by illumination of an energy beam. The energy beam denotes an electron beam, ultraviolet light, infrared light, laser light, visible light, ionizing radiation (X ray, α ray, β ray, γ ray or the like), a microwave, a high frequency wave, or the like, where the energy beam may be used as a trigger of a polymerization reaction of radicals, cations, anions, or the like. According to necessity, the energy beam curable resin composition 118 may be mixed with another resin in use. For example, the energy beam curable resin composition 118 may be mixed with anther curable resin such as a thermosetting resin. In addition, the energy beam curable resin composition 118 may be an organic-inorganic hybrid material. In addition, two or more types of the energy beam curable resin compositions may be mixed and used. A UV curable resin which is cured by ultraviolet light may be preferably used as the energy beam curable resin composition 118.

The UV curable resin is made of, for example, a monofunctional monomer s, bifunctional monomers, multifunctional monomers, initiators, and the like. More specifically, the UV curable resin may be made of one of the following listed materials or a mixture thereof.

The monofunctional monomers may include, for example, carboxylic acid series (acrylic acid), or hydroxy series (2-hydroxyethyl acrylate, 2-hydroxypropyl acrylate, 4-hydroxybutyl acrylate), alkyl, alicyclic series (iso-butyl acrylate, t-butyl acrylate, isooctyl acrylate, lauryl acrylate, stearyl acrylate, isobornyl acrylate, cyclohexyl acrylate), other functional monomers (2-methoxyethyl acrylate, methoxyethyl ethylene glycol acrylate, 2-ethoxyethyl acrylate, tetrahydrofurfuryl acrylate, benzyl acrylate, ethyl carbitol acrylate, phenoxyethyl acrylate, N,N-dimethylaminoethyl acrylate, N,N-dimethylaminopropyl acrylamide, N,N-dimethyl acrylamide, acryloyl morpholine, N-isopropyl acrylamide, N,N-diethyl acrylamide, N-vinylpyrrolidone, 2-(perfluorooctyl) ethyl acrylate, 3-perfluorohexyl 2-hydroxypropyl acrylate, 3-perfluorooctyl 2-hydroxypropyl acrylate, 2-(perfluorodecyl)ethyl acrylate, 2-(perfluoro-3-methylbutyl) ethyl acrylate), 2,4,6-tribromophenol acrylate, 2,4,6-tribromophenol methacrylate, 2-(2,4,6-tribromophenoxy) ethyl acrylate), and 2-ethylhexyl acrylate), and the like.

The bifunctional monomers may include, for example, tri(propylene glycol) diacrylate, trimethylolpropane diallyl ether, urethane acrylate, and the like.

The multifunctional monomers may include, for example, trimethylolpropane triacrylate, dipentaerythritol penta and hexa acrylate, ditrimethylolpropane tetraacrylate, and the like.

The initiators may include, for example, 2,2-dimethoxy-1,2-diphenylethane-1-one, 1-hydroxycyclophenyl ketone, 2-hydroxy-2-methyl-1-phenylpropan-1-one, and the like.

In addition, according to necessity, the energy beam curable resin composition 118 may include a filler, a functional additive, a solvent, an inorganic material, a pigment, an antistatic agent, a sensitizing dye, or the like. As the filler, for example, all inorganic particles and organic particles may be used. As the inorganic particle, for example, metal oxide particles such as SiO₂, TiO₂, ZrO₂, SnO₂, or Al₂O₃ may be exemplified. As the functional additive, for example, a leveling agent, a surface control agent, an absorbent, a defoamer, or the like may be exemplified.

Next, while the roll master disc 101 is rotated, the transfer surface Sp thereof is closely attached to the energy beam curable resin composition 118, and the energy beam curable resin composition 118 is illuminated with an energy beam, for example, through the substrate 102 or the roll master disc 101. By doing so, the energy beam curable resin composition 118 is cured, so that the shape layer 30 is formed. The presence of a base layer 3b or the thickness of the base layer 3b may be selected, for example, by adjusting a pressure of the roll master disc 101 to the surface of the substrate 102.

In the case of illumination of the energy beam through the substrate 102, it is preferable that the substrate 102 have transparency with respect to the illuminated energy beam. The material of the substrate 102 is not particularly limited, but it may be appropriately selected according to its use. For example, plastics such as methyl methacrylate (co)polymer, polycarbonate, styrene (co)polymer, methyl methacrylate-styrene copolymer, cellulose diacetate, cellulose triacetate, cellulose acetate butyrate, polyester, polyamide, polyimide, polyether sulfone, polysulphone, polypropylene, polymethyl pentene, polyvinyl chloride, polyvinyl acetal, polyether ketone, polyurethane, cycloolefin polymer, cycloolefin copolymer, glass, magnetic materials, and semiconductors may be used.

Next, the shape layer 30 formed on the substrate 102 is peeled off from the transfer surface Sp of the roll master disc 101. By doing so, as illustrated in FIG. 6D, the laminated structure where the shape layer 30 is formed on the surface of the substrate 102 may be obtained. In the transfer process, the convex-concave shape may be transferred in the state where the longitudinal direction of the substrate 102 having a belt shape is set to the rotation movement direction of the roll master disc 101.

(Transparent Conductive Layer Forming Process)

Next, the transparent conductive layer 4 is formed on the convex-concave surface of the structural elements 3. As the method of forming the transparent conductive layer 4, for example, as well as a CVD method (Chemical Vapor Deposition method: a technique of depositing a thin film from a vapor phase by using a chemical reaction) such as thermal CVD, plasma CVD, or optical CVD, a PVD method (Physical Vapor Deposition method: a technique of forming a thin film by aggregating a material, which is evaporated in vacuum, on a substrate) such as vacuum deposition, plasma assisted deposition, sputtering, or ion plating may be used.

In the aforementioned example, although it is configured so that the conductive optical device 1 is obtained by forming the transparent conductive layer 4 with respect to the laminated structure of the shape layer 30 including the structural elements 3 and the substrate 102, the structural elements 3 may be integrally formed with respect to the substrate 2.

### 2. Second Embodiment

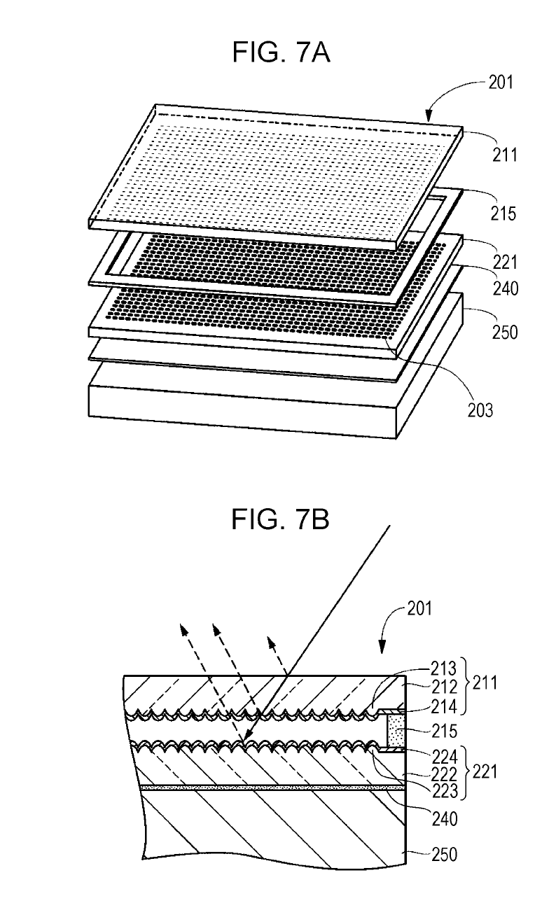

FIG. 7A is a perspective diagram illustrating an example of a configuration of a touch panel according to a second embodiment of the present disclosure. FIG. 7B is a cross-sectional diagram illustrating an example of a configuration of a touch panel according to the second embodiment of the present disclosure. The touch panel is a so-called resistive film type touch panel. The resistive film type touch panel may be one of an analog resistive film type touch panel and a digital resistive film type touch panel.

As illustrated in FIG. 7A, the touch panel 201 which is an information input apparatus includes a first conductive optical device 211 having a touch surface (input surface) where information is input and a second conductive optical device 221 facing the first conductive optical device 211. The first conductive optical device 211 and the second conductive optical device 221 are adhered to each other through an adhesive layer 215 which is disposed between the circumferential portions thereof. As the adhesive layer 215, for example, an adhesive paste, an adhesive tape, or the like may be used. The touch panel 201 is adhered, for example, to the display apparatus 250 through an adhesive layer 240. As a material of the adhesive layer 240, for example, an acrylic adhesive, a rubber adhesive, a silicon adhesive or the like may be used. In terms of the transparence, an acrylic adhesive is preferred.

As the display apparatus, for example, various display apparatuses such as a plasma display (Plasma Display Panel: PDP), an electro luminescence (EL) display, a surface-conduction electron-emitter display (SED), or the like may be used.

The conductive optical device 1 according to the first embodiment is used as at least one of the first conductive optical device 211 and the second conductive optical device 221.

The structural elements 213 are formed on at least one of the two facing surfaces of the first conductive optical device 211 and the second conductive optical device 221. The aspect ratio of the structural elements 213 is configured to be equal to or more than 0.1 and equal to or less than 1.8. In terms of simultaneously implementing the bendability, the low resistance, and the high transmittance of the transparent conductive film of the touch panel, it is preferable that the structural elements 213 be formed on both of the two surfaces. A transparent conductive layer 214 is formed on the structural elements 213. The transparent conductive layer 214 includes a surface emulating the structural elements 213.

In the second embodiment, since the transparent conductive layer 214 is formed on the structural elements 213 of which the aspect ratio is equal to or more than 0.1 and equal to or less than 1.8, the conductivity of the conductive optical device where the structural elements 213 and the transparent conductive layer 214 are formed is maintained with respect to the bending test. Therefore, with respect to the conductive optical device constituting the touch panel, it is possible to secure the transmittance and the surface resistance value which are necessary to the transparent conductive film of the touch panel and to obtain excellent bendability. In addition, in the case where the touch panel according to the second embodiment is combined with a flexible display apparatus, for example, a flexible organic EL display or the like, it is possible to obtain an information input apparatus having excellent bendability.

A single-layered or multi-layered reflection preventing layer may be formed on the surface of the first conductive optical device 211 which becomes the touch side. This is because the reflectance is reduced, so that it is possible to improve visibility. In addition, a plurality of the structural elements may be arranged with the fine pitch which is equal to or less than the wavelength of visible light on the touch surface in addition to the inner portion of the touch panel 201. A plurality of the structural elements may further be arranged on the rear surface of the side which is adhered on the display apparatus 250.

The surface of the first conductive optical device 211 which becomes the touch side may further include a hard coat layer or an antifouling hard coat layer. This is because it is possible to improve the excoriation resistance of the touch surface of the touch panel 201. According to necessity, a front panel may further be included on the touch panel 201.

In the first substrate 212 or the second substrate 222, in the case where the circumferential member such as the wire layer is formed in the circumferential portion of the area where the structural elements are formed, a plurality of structural elements may be formed in the circumferential portion. This is because it is possible to improve the adhesion of the circumferential member such as the wire layer and the substrate.

### First Modified Example of Second Embodiment

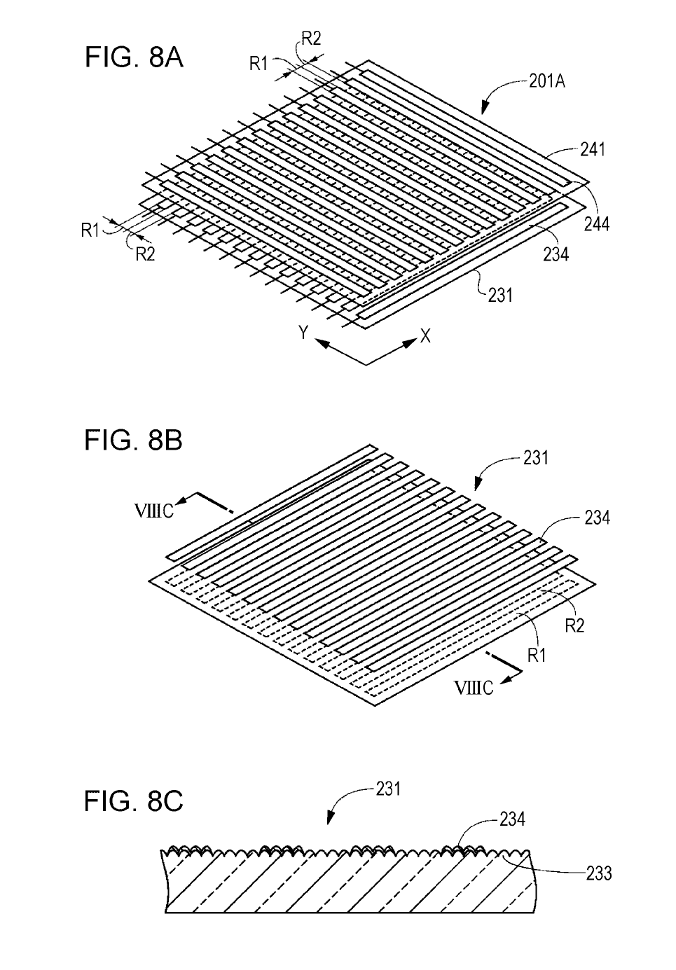

FIG. 8A is a perspective diagram illustrating a first modified example of a touch panel according to a first modified example of the second embodiment. The touch panel 201A is a matrix resistive film type touch panel. The touch panel 201A includes a first conductive optical device 231 and a second conductive optical device 241 which are arranged to face each other to be separated by a predetermined gap through dot spacers (not shown).

FIG. 8B is a fragmented perspective diagram illustrating an example of a configuration of the first conductive optical device. FIG. 8C is a schematic cross-sectional diagram taken along line VIIIC-VIIIC of FIG. 8B. In addition, since the configuration of the second conductive optical device 241 is substantially the same as that of the first conductive optical device 231, the description of the fragmented perspective diagram is omitted.

First rectangular areas R1 and second rectangular areas R2 are set to alternately repeat on the one main surface facing the second conductive optical device 241 among the two main surfaces of the first conductive optical device 231. The surface of the first conductive optical device 231 has the same structure as that of the surface of the substrate in the conductive device according to the aforementioned embodiment in that a plurality of the structural elements 233 are arranged, for example, with the arrangement pitch which is equal to or less than the wavelength of visible light. The surface of the first conductive optical device 231 in the first modified example of the second embodiment has a structure different from the surface of the substrate in the conductive device according to the aforementioned embodiment in that the transparent conductive layer is continuously formed, for example, on only the surface of the first conductive optical device in the first area R1. Therefore, a plurality of the horizontal (X) electrodes (first electrode) 234, which are constructed with the transparent conductive layer formed continuously, are formed in a stripe shape on the one main surface facing the second conductive optical device 241 among the two main surfaces of the first conductive optical device 231.

The first rectangular area R1 and the second rectangular area R2 are set to alternately repeat on the one main surface facing the first conductive optical device 231 among the two main surfaces of the second conductive optical device 241. The surface of the second conductive optical device 241 has the same structure as that of the surface of the substrate in the conductive device according to the aforementioned embodiment in that a plurality of the structural elements are arranged, for example, with the arrangement pitch which is equal to or less than the wavelength of visible light. The surface of the first conductive optical device 241 in the first modified example of the second embodiment has a structure different from the surface of the substrate in the conductive device according to the aforementioned embodiment in that the transparent conductive layer is continuously formed, for example, on only the surface of the first conductive optical device in the first area R1. Therefore, a plurality of the vertical (Y) electrodes (second electrode) 244, which are constructed with the transparent conductive layer formed continuously, are formed in a stripe shape on the one main surface facing the first conductive optical device 231 among the two main surfaces of the second conductive optical device 241.

The first area R1 and the second area R2 of the first conductive optical device 231 and the second conductive optical device 241 have a relationship where the first area R1 and the second area R2 are perpendicular to each other. In other words, the horizontal electrode 234 of the first conductive optical device 231 and the vertical electrode 244 of the second conductive optical device 241 have a relationship where the horizontal electrode 234 and the vertical electrode 244 are perpendicular to each other.

The structural elements of which the aspect ratios of the first area R1 and the second area R2 are different from each other may be formed. By doing so, it is possible to further improve the reflection preventing characteristic and/or the transmission characteristic of the touch panel 201A.

### Second Modified Example of Second Embodiment

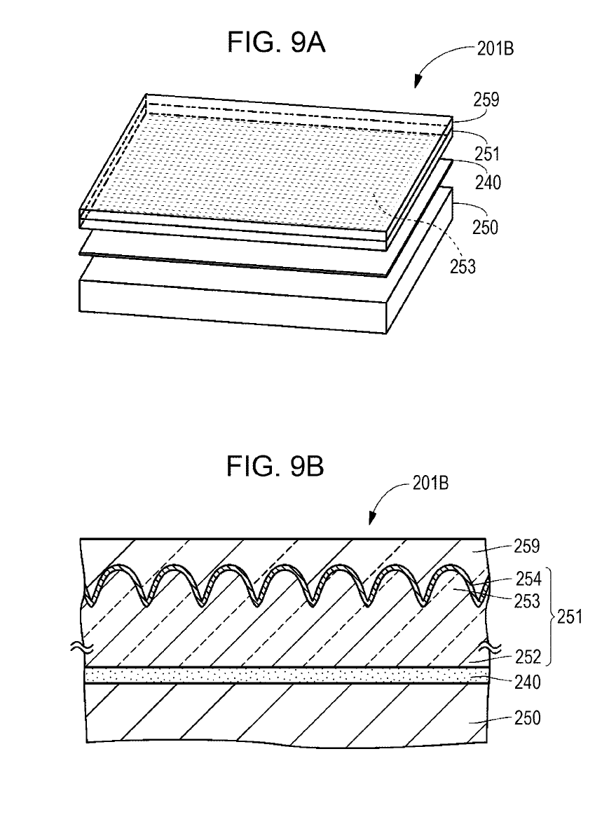

FIG. 9A is a perspective diagram illustrating an example of a configuration of a touch panel according to a second modified example of the second embodiment. FIG. 9B is a cross-sectional diagram illustrating the example of the configuration of the touch panel according to the second modified example of the second embodiment. The touch panel 201B is a so-called capacitive touch panel. A plurality of structural elements 253 are formed in an inner portion thereof. The touch panel 201B is adhered on the display apparatus 250, for example, through an adhesive layer 240.

As illustrated in FIGS. 9A and 9B, the touch panel 201B according to the second modified example of the second embodiment includes a substrate 252, a transparent conductive layer 254 formed on the substrate 252, and a protective layer 259. A plurality of the structural elements 253 are arranged with the fine pitch which is equal to or less than the wavelength of visible light on at least one of the substrate 252 and the protective layer 259.

The protective layer 259 is a dielectric layer which includes a dielectric material, for example, SiO₂ or the like as a main component. The transparent conductive layer 254 has different configurations according to the type of the touch panel 201B. For example, in the case where the touch panel 201B is a surface type capacitive touch panel, the transparent conductive layer 254 is a thin film having a substantially constant thickness. In the case where the touch panel 201B is a projection type capacitive touch panel, the transparent conductive layer 254 is a transparent electrode pattern of lattice shapes or the like which are arranged with a predetermined pitch. As a material of the transparent conductive layer 254, the aforementioned materials of the first embodiment may be used.

### Third Modified Example of Second Embodiment

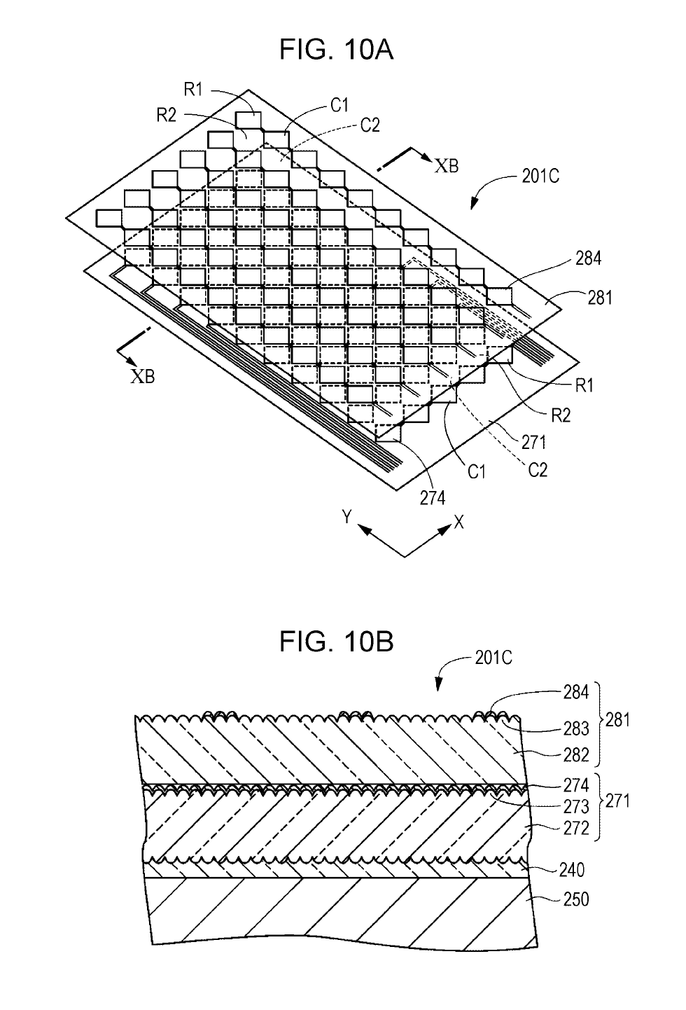

FIG. 10A is a perspective diagram illustrating an example of a configuration of a touch panel according to a third modified example of the second embodiment. FIG. 10B is a cross-sectional diagram taken along line XA-XA of FIG. 10A. The touch panel 201C is an ITO Grid, projection type capacitive touch panel. The touch panel 201C includes a first conductive optical device 271 and a second conductive optical device 281 which are overlapped with each other.

In the example illustrated in FIGS. 10A and 10B, the first area R1 and the second area R2 are set to alternately repeat on the one main surface facing the second conductive optical device 281 among the two main surfaces of the first conductive optical device 271, and the adjacent first areas R1 are separated by the second area R2. The first area R1 and the second area R2 are set to alternately repeat on the one main surface of the side opposite to the side facing the first substrate 272 among the two main surfaces of the second conductive optical device 281, and the adjacent first areas R1 are separated by the second area R2. The surface structures of the first conductive optical device 271 and the second conductive optical device 281 are the same as those of the conductive device of the aforementioned first modified example in that the transparent conductive layer is continuously formed only on the surface of the first area R1.

The first area R1 of the first conductive optical device 271 is formed by repetitively connecting the unit areas C1 having a predetermined shape in the X axis direction, and the second area R2 is formed by repetitively connecting the unit areas C2 having a predetermined shape in the X axis direction. The first area R1 of the second conductive optical device 281 is formed by repetitively connecting the unit areas C1 having a predetermined shape in the Y axis direction, and the second area R2 is formed by repetitively connecting the unit areas C2 having a predetermined shape in the Y axis direction. As the shape of the unit area C1 and the shape of the unit area C2, for example, a diamond shape (rhombic shape), a triangular shape, a rectangular shape, or the like may be exemplified, but the present disclosure is not limited to the shapes.

The surface of the first substrate 272 in the first area R1 is a wave surface where a plurality of the structural elements 273 are formed, for example, with the arrangement pitch which is equal to or less than the wavelength of visible light, and a transparent conductive layer is formed on the structural elements 273. Similarly, the surface of the second substrate 282 in the first area R1 is a wave surface where a plurality of the structural elements 283 are formed, for example, with the arrangement pitch which is equal to or less than the wavelength of visible light, and a transparent conductive layer is formed on the structural elements 283. Therefore, a plurality of the horizontal (X) electrodes (first electrodes) 274 which is constructed with the transparent conductive layer are arranged on the one main surface facing the second substrate 282 among the two main surfaces of the first substrate 272. In addition, a plurality of the vertical (Y) electrodes (second electrodes) 284 which is constructed with the transparent conductive layer are arranged on the one main surface which is the side opposite to the side facing the first substrate 272 among the two main surfaces of the second substrate 282.

The horizontal electrode 274 of the first substrate 272 and the vertical electrode 284 of the second substrate 282 have a relationship where the horizontal electrode 274 and the vertical electrode 284 are perpendicular to each other. In the state where the first conductive optical device 271 and the second conductive optical device 281 overlap each other, the first area R1 of the first substrate 272 and the second area R2 of the second substrate 282 overlap each other; and the second area R2 of the first substrate 272 and the first area R1 of the second substrate 282 overlap each other.

As illustrated in FIG. 10B, a plurality of the structural elements may be formed on the surface of the side of the first conductive optical device 271, which is attached on the display apparatus. By doing so, it is possible to improve the transmission characteristic of the touch panel.

### 3. Third Embodiment

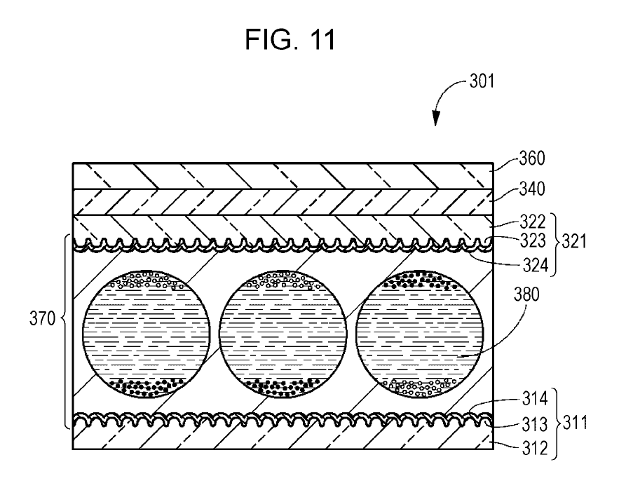

FIG. 11 is a schematic cross-sectional diagram illustrating an example of a configuration of a display apparatus according to a third embodiment of the present disclosure. The display apparatus 301 is a so-called microencapsulated electrophoretic type electronic paper. The display apparatus 301 includes a first conductive optical device 311, a second conductive optical device 321 which is disposed to face the first conductive optical device 311; and a microencapsulated layer (medium layer) 370 which is disposed between the above two devices. Herein, although the example where the present disclosure is adapted to the microencapsulated electrophoretic type electronic paper, is described, the electronic paper is not limited to the example. If a medium layer is disposed between the pattern substrates which are disposed to face each other, the present disclosure may be adapted thereto. Herein, the medium also includes a gas such as air as well as a liquid or a solid. In addition, the medium may contain members of capsules, pigments, particles, or the like. Besides the microencapsulated electrophoretic type electronic paper, as an electronic paper which the present disclosure may be adapted to, for example, a twisted ball type electronic paper, a thermal rewritable type electronic paper, a toner display type electronic paper, an in-plane electrophoretic type electronic paper, a granular electron type electronic paper, and the like may be exemplified.

The microencapsulated layer 370 includes a plurality of microcapsules 380. For example, transparent liquid (dispersion medium) where black particles or white particles are dispersed are sealed in the microcapsules.

The conductive optical device 1 according to the first embodiment is used as at least one of the first conductive optical device 311 and the second conductive optical device 321. In the example illustrated in FIG. 11, the first conductive optical device 311 is constructed with a first substrate 312 and a transparent conductive layer 314. The first substrate 312 includes a plurality of structural elements 313 which are formed with the arrangement pitch which is equal to or less than the wavelength of, for example, visible light on the surface of the side thereof which faces the second conductive optical device 321. The transparent conductive layer 314 is formed on the structural elements 313. On the other hand, the second conductive optical device 321 is constructed with a second substrate 322 and a transparent conductive layer 324. The second substrate 322 includes a plurality of structural elements 323 which are formed with the arrangement pitch which is equal to or less than the wavelength of, for example, visible light on the surface of the side thereof which faces the first conductive optical device 311. The transparent conductive layer 324 is formed on the structural elements 323. According to necessity, the first conductive optical device 311 may be adhered on a supporting member 360 such as glass through an adhesive layer 340 such as an adhesive.

The transparent conductive layer 314 and the transparent conductive layer 324 are formed in a predetermined electrode pattern according to a driving type of the electronic paper 301. As the driving type, for example, a simple matrix driving type, an active matrix driving type, a segment driving type, or the like may be exemplified.

In the third embodiment, since the transparent conductive layer is formed on the structural elements of which the aspect ratio is equal to or more than 0.1 and equal to or less than 1.8, it is possible to secure the transmittance and the surface resistance value of the transparent conductive film constituting the display apparatus and to obtain excellent bendability thereof.

### 4. Fourth Embodiment

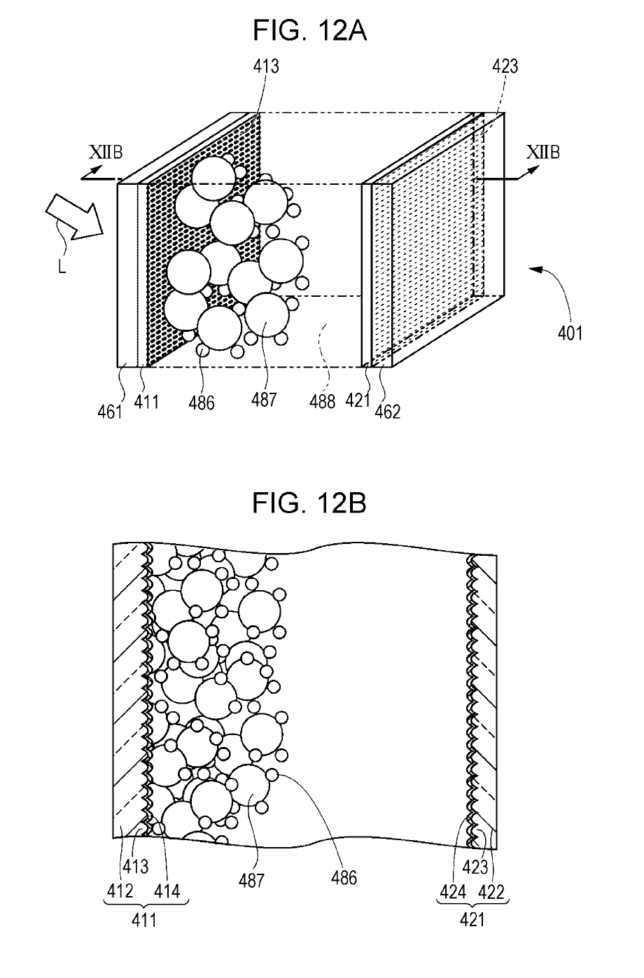

FIG. 12A is a schematic perspective diagram illustrating an example of a configuration of an electrochemical device according to a fourth embodiment of the present disclosure. FIG. 12B is a cross-sectional diagram taken along line XIIB-XIIB of FIG. 12A. The electrochemical device 401 is a so-called dye-sensitized solar cell. The electrochemical device 401 includes a first conductive optical device 411, a second conductive optical device 421, and semiconductor particles 487 where an electrolyte 488 and dyes 486 are contained therebetween. The dye 486 expresses a sensitization action with respect to incident light L. In addition, although FIG. 12A illustrates an example where the first conductive optical device 411 and the second conductive optical device 421 are adhered on a supporting member 461 and a supporting member 462, which are constructed with glass or the like, respectively, the supporting member 461 and the supporting member 462 are disposed according to necessity. In the illustration of FIG. 12B, the supporting member 461 and the supporting member 462 are omitted. In addition, the dyes 486 and the semiconductor particles 487 are illustrated as having a large size for the convenience of description, but the illustrated sizes thereof are not the actual sizes thereof.

A conductive optical device similar to the conductive optical device according to the first embodiment is used as at least one of the first conductive optical device 411 and the second conductive optical device 421.

In the example illustrated in FIGS. 12A and 12B, structural elements 413 and structural elements 423 are formed on the two facing surfaces of the first substrate 412 and the second substrate 422, respectively. A transparent conductive layer 414 is formed on the structural elements 413, and the transparent conductive layer 414 has a surface emulating the structural elements 413. In addition, a transparent conductive layer 424 is formed on the structural elements 423, and the transparent conductive layer 424 has a surface emulating the structural elements 423. In addition, in the example illustrated in FIG. 12A, although the light L is incident on the semiconductor particles 487, where the dyes 486 are supported, from the outer side (the side where the supporting member 461 is attached in FIG. 12A) of the first conductive optical device 411, it may be configured so that the light L is incident from the outer side of the second conductive optical device 421. In addition, it may be configured so that the light is incident from the outer side of the first conductive optical device 411 and the outer side of the second conductive optical device 421.

A layer of the semiconductor particles 487 where the dyes 486 showing a sensitization action to the incident light L are supported is formed on the surface of the side facing the second conductive optical device 421 among the main surfaces of the first conductive optical device 411. In other words, the light electrode of the dye-sensitized solar cell is constructed with the transparent conductive layer 414 and the layer of the semiconductor particles 487 where the dyes 486 are supported. On the other hand, the transparent conductive layer 424 formed on the structural elements 423 has a function as the opposite electrode of the dye-sensitized solar cell.

The light L which is incident on the electrochemical device 401 from the outer side of the first conductive optical device 411 transmits the first conductive optical device 411 to be incident on the light electrode. The light L which is incident on the layer of the semiconductor particles 487 where the dyes 486 showing a sensitization action to the incident light L are supported excites the dyes 486, so that electrons are generated. The electrons are rapidly delivered from the dyes 486 to the semiconductor particles 487. On the other hand, dyes 486 losing the electrons receive electrons from ions of the electrolyte 488, and molecules delivering the electrons receive electrons from the surface of the opposite electrode. In the series of reactions, an electromotive force is generated between the first conductive optical device 411 and the second conductive optical device 421 which are electrically connected to the layer of the semiconductor particles 487 where the dyes 486 are supported. In this manner, the photoelectric conversion is performed.

In the fourth embodiment, the first conductive optical device 411 and the second conductive optical device 421 are used as the members constituting the electrodes of the dye-sensitized solar cell. Therefore, it is possible to simultaneously implement the low resistance and the high transmittance necessary for the electrodes of the dye-sensitized solar cell and to obtain an excellent bendability of the dye-sensitized solar cell.

### EMBODIMENTS

Hereinafter, the present disclosure will be described in detail by the embodiments. However, the present disclosure is not limited to the embodiments.

In the embodiments described hereinafter, the bending test is performed by changing the aspect ratio of the structural elements formed on the surface of the conductive optical device, and the bendability of the conductive optical device is checked by comparing the interterminal resistances of the conductive optical device before and after the bending test.

(Sample 1-1)

First, a glass roll master disc having an outer diameter of 126 mm is prepared, and a resist layer is attached on the surface of the glass roll master disc. Next, the glass roll master disc as a recording medium is transferred to the roll master disc exposing apparatus illustrated in FIG. 4, and the exposing is performed on the resist layer, so that a latent image having a hexagonal lattice pattern among the three adjacent columns of the tracks is patterned on the resist layer.

Next, a developing process is applied to the resist layer on the glass roll master disc to dissolve the resist layer in the exposed portion so that the developing is performed. By doing so, a resist glass master disc where the resist layer is opened in the hexagonal lattice pattern is obtained.

Next, plasma etching is performed in a CHF₃ gas atmosphere, concave portions having an elliptical cone shape are obtained on the surface of the glass roll master disc. At this time, the etching amount (depth) of the pattern is changed by the etching time. Finally, the resist layer is completely removed by O₂ ashing, so that the roll master disc is obtained.

Next, the roll master disc and an acryl sheet which a UV curable resin is applied are closely adhered to each other, and the peeling is performed while the curing is performed with illumination of ultraviolet light. By doing so, an optical sheet where a plurality of the structural elements are arranged on one main surface is obtained. Next, an ITO film having a thickness of 110 nm is formed on the structural elements by a sputtering method.

Next, the conductive optical device of the sample 1-1 is obtained by cutting the optical sheet where the ITO film is formed into a rectangular shape of 5 mm×25 mm.

The pitch and the height of the structural elements of the sample 1-1 manufactured as described above are measured, so that the values of 250 nm and 155 nm are obtained. In other words, the aspect ratio of the structural elements of the sample 1-1 is 0.62.

(Sample 1-2)

The conductive optical device of the sample 1-2 is obtained in the same conditions of the conductive optical device of the sample 1-1 excluding that the pitch and the height of the structural elements are set to 250 nm and 120 nm, respectively, and the aspect ratio is set to 0.48.

(Sample 1-3)

The conductive optical device of the sample 1-3 is obtained in the same conditions of the conductive optical device of the sample 1-1 excluding that the pitch and the height of the structural elements are set to 250 nm and 90 nm, respectively, and the aspect ratio is set to 0.36.

(Sample 2-1)

The conductive optical device of the sample 2-1 is obtained in the same conditions of the conductive optical device of the sample 1-1 excluding that the pitch and the height of the structural elements are set to 250 nm and 10 nm, respectively, and the aspect ratio is set to 0.04.

(Sample 3-1)

The structural elements are not transferred, an ITO film having a thickness of 110 nm is formed on an acryl sheet, so that a conductive optical device of the sample 3-1 is obtained.

The surface resistance of each of the sample 1-1 to the sample 1-3, the sample 2-1, and the sample 3-1 is measured by the four-terminal method. With respect to each of the sample 1-1 to the sample 1-3, the sample 2-1, and the sample 3-1, the relation between the aspect ratio and the measured value of the surface resistance is listed in Table 1.

TABLE 1

| | Aspect | Pitch | Height | Surface Resistance |
|---|---|---|---|---|
| No. | Ratio | (nm) | (nm) | (Ω/ ) |
| Sample 1-1 | 0.62 | 250 | 155 | 173 |
| Sample 1-2 | 0.48 | 250 | 120 | 100 |
| Sample 1-3 | 0.36 | 250 | 90 | 65 |
| Sample 2-1 | 0.04 | 250 | 10 | 143 |
| Sample 3-1 | 0 | 0 | 0 | 51 |

(Bending Test)

First, the interterminal resistance of each of the sample 1-1 to the sample 1-3, the sample 2-1, and the sample 3-1 is measured by the four-terminal method.

Next, each sample is wound around the φ4 metal bar in the state where the surface where the structural elements are formed is to be the inner side and the longitudinal direction of the rectangular shape is set to be along the circumferential direction, and thereafter, each sample is returned to its original state. Herein, φ4 indicates that the diameter of the metal bar is 4 mm, and this is the same in the following description.

Next, with respect to each sample after the winding around the φ4 metal bar, the interterminal resistance thereof is measured by a four-terminal method. The ratio between the measured value of the interterminal resistance after the winding around the φ4 metal bar and the measured value of the interterminal resistance before the winding (no bending) is set as the resistance change rate ΔR(φ4), and the ΔR (φ4) with respect to each sample is obtained. In other words, the resistance change rate ΔR (φ4) is defined by the relationship expressed by the following Equation (4).

ΔR(φ4)=Interterminal Resistance(φ4)Ω/Interterminal Resistance(No Bending)Ω (4)

The resistance change rates ΔR (φ4) obtained with respect to the sample 1-1 to the sample 1-3, the sample 2-1, and the sample 3-1 are listed in Table 2.

In addition, marks “O” and “X” in the column of resistance change in Table 2 indicates evaluation results, as follows.

O: the change of the measured value of the interterminal resistance is in a range of equal to or less than 50%.

X: the change of the measured value of the interterminal resistance exceeds 50%.

TABLE 2

| | | | | | | resistance | |
|---|---|---|---|---|---|---|---|
| | Interterminal Resistance (Ω): 5 × 25 | | | | | change | |
| | No | | | | | rate ΔR | resistance |
| No. | Bending | φ16 | φ8 | φ4 | φ2 | (φ4) | change |
| Sample | 1000 | 1000 | 1000 | 1000 | 960 | 1.00 | O |
| 1-1 | | | | | | | |
| Sample | 550 | 550 | 550 | 550 | 530 | 1.00 | O |
| 1-2 | | | | | | | |
| Sample | 304 | 310 | 319 | 326 | 483 | 1.07 | O |
| 1-3 | | | | | | | |
| Sample | 800 | 840 | 5000 | 8000 | 12000 | 10.00 | X |
| 2-1 | | | | | | | |
| Sample | 275 | 280 | 274 | 420 | 1100 | 1.53 | X |
| 3-1 | | | | | | | |

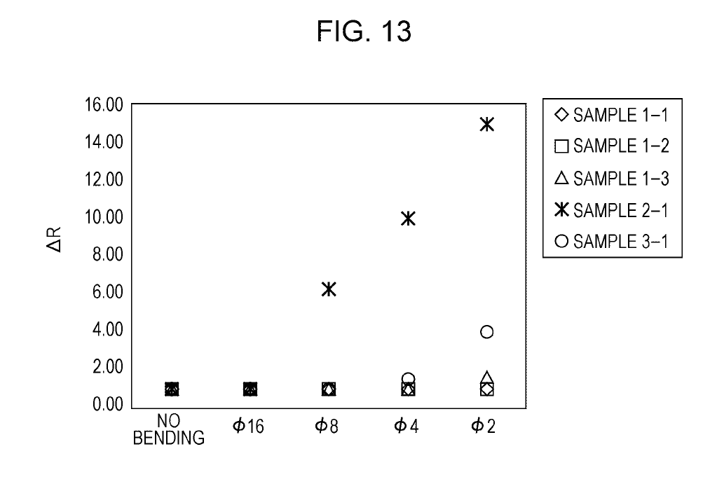

In addition, the same measurement is performed with respect to the winding around the φ2, φ8, and φ16 metal bars. The measured values of the interterminal resistance obtained with respect to the sample 1-1 to the sample 1-3, the sample 2-1, and the sample 3-1 are listed in Table 2. The resistance change rates AR obtained with respect to the sample 1-1 to the sample 1-3, the sample 2-1, and the sample 3-1 are listed in FIG. 13.

The following results may be understood from Table 2 and FIG. 13.

In general, although there is a tendency in that the value of the surface resistance of the obtained the conductive optical device is changed according to the condition of formation of the ITO film, it may be understood that, in the case where the aspect ratio of the structural elements are set to be equal to or more than 0.1 and equal to or less than 1.8, it is possible to maintain the conductivity with respect to the bending test. For example, it is confirmed that there is a clear difference between the resistance change of the sample 1-1 to the sample 1-3 and the resistance change of the sample 2-1. In addition, the sample 2-1 and the sample 3-1 after wounding around the 44 metal bar are visually observed, and the states thereof are cloudy white. It is estimated that this is because a plurality of cracks occur in the transparent conductive layer formed as an ITO film due to the bending. In other words, in the estimation of the resistance change, it is understood that the sample allocated the mark “X” may not have a sufficient bendability.

For the results of the bending test hereinbefore, a plurality of the structural elements arranged with the fine pitch which is equal to or less than the wavelength of visible light are formed on the surface of the conductive optical device, and in the case where the transparent conductive layer is formed on the structural elements, the aspect ratio of the structural elements is set to be equal to or more than 0.1 and equal to or less than 1.8, and the transparent conductive layer has the surface emulating the structural elements, so that it is possible to maintain the conductivity of the conductive optical device with respect to the bending test. Therefore, it is possible to implement a conductive optical device capable of securing the low resistance and the high transmittance and maintaining the conductivity with respect to the bending test.

Hereinbefore, although the specific embodiments of the present disclosure are described, the present disclosure is not limited to the aforementioned embodiments, and various modifications are available based on the technical spirit of the present disclosure.

For example, the configurations, the methods, the processes, the shapes, the materials, the numerical values, and the like in the aforementioned embodiments are only exemplary, and thus, according to necessity, other configurations, methods, processes, shapes, materials, numerical values, and the like may be used.

The configurations, the methods, the processes, the shapes, the materials, the numerical values, and the like in the aforementioned embodiments may be combined in use thereof without departing from the spirit of the present disclosure.

In the aforementioned embodiments, although the example of transferring the structural elements formed on the roll master disc is described, the present disclosure is not limited to the example, and a rectangular shaped master disc, a disc-shaped master disc, or the like may be used.

In addition, in the aforementioned embodiments, although a convex shape is exemplified as an example of the structural element, for example, a structural element having a concave shape formed by inverting the convex shape illustrated in FIG. 1C may be used.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A conductive optical device comprising:
a substrate having flexibility;
structural elements which are constructed with a plurality of convex portions or concave portions with a fine pitch which is equal to or less than a wavelength of visible light arranged on a surface of the substrate; and
a transparent conductive layer which is formed on the structural elements,
wherein the aspect ratio of the structural elements is equal to or more than 0.1 and equal to or less than 1.8,
wherein the transparent conductive layer has a surface emulating the structural elements, and
wherein a conductivity with respect to a bending test is maintained.

2. The conductive optical device according to claim 1, wherein a surface resistance of the transparent conductive layer is in a range of equal to or more than 50Ω/and less than 500Ω/.

3. The conductive optical device according to claim 1, wherein a thickness of the transparent conductive layer in a top portion of the structural element is in a range of equal to or more than 5 nm and equal to or less than 150 nm.

4. The conductive optical device according to claim 1,
wherein the structural elements are arranged so as to constitute a plurality of columns of tracks on the surface of the substrate, and
wherein the tracks have a straight line shape or an arc shape.

5. The conductive optical device according to claim 1,
wherein the structural elements are arranged so as to constitute a plurality of columns of tracks on the surface of the substrate, and
wherein the tracks are formed to meander.

6. The conductive optical device according to claim 1,
wherein the structural elements are arranged so as to constitute a plurality of columns of tracks on the surface of the substrate, and
wherein the structural elements are configured to form a hexagonal lattice pattern, a quasi-hexagonal lattice pattern, a square lattice pattern, or a quasi-square lattice pattern.

7. The conductive optical device according to claim 1,
wherein the structural elements are arranged so as to constitute a plurality of columns of tracks on the surface of the substrate, and
wherein the structural element has an elliptical cone shape or a truncated elliptical cone shape having the direction of a longest axis in the track extension direction.

8. The conductive optical device according to claim 1, wherein the structural element has an elliptical cone shape having a curved surface on a top portion thereof.

9. The conductive optical device according to claim 1,
wherein the substrate has another surface of the side opposite to the surface, and
wherein the conductive optical device further includes structural elements which are constructed with a plurality of convex portions or concave portions with a fine pitch which is equal to or less than the wavelength of visible light arranged on the other surface of the substrate.

10. The conductive optical device according to claim 1, wherein a packing ratio of the structural elements with respect to the surface of the substrate is equal to or more than 65%.

11. The conductive optical device according to claim 10, wherein the packing ratio of the structural elements with respect to the surface of the substrate is equal to or more than 73%.

12. The conductive optical device according to claim 1, wherein the ratio ((2r/P1)×100) of the diameter 2r to the arrangement pitch P1 of the structural elements is equal to or more than 85%.

13. The conductive optical device according to claim 12, wherein the ratio ((2r/P1)×100) of the diameter 2r to the arrangement pitch P1 is equal to or more than 90%.

14. The conductive optical device according to claim 1, wherein the transparent conductive layer is a transparent electrode pattern.

15. An information input apparatus having the conductive optical device according to claim 1.

16. A display apparatus having the conductive optical device according to claim 1.
